(19) United States
(12) Patent Application Publication
(10) Pub. No.: US 2026/0361312 A1
(43) Pub. Date: Nov. 12, 2026

(54) SUCCESSIVE APPROXIMATION ANALOG-TO-DIGITAL CONVERTER, AND CORRESPONDING METHOD

(71) Applicant: STMicroelectronics International N.V., Geneva (CH)

(72) Inventor: Evgeny KULKOV, Munich (DE)

(73) Assignee: STMicroelectronics International N.V., Geneva (CH)

(21) Appl. No.: 19/668,133

(22) Filed: May 5, 2026

(30) Foreign Application Priority Data
May 8, 2025 (IT) 102025000010419

(51) Int. Cl. H03M 1/06

(52) U.S. Cl. CPC H03M 1/0607

(57) ABSTRACT

A SAR ADC includes positive and negative input terminals, a first capacitive-DAC having a first capacitor-bank including capacitances selectively couplable to the positive input terminal, a reference-voltage, or a ground, and a second capacitive-DAC having a second capacitor-bank including capacitances selectively couplable to the negative input terminal, reference-voltage, or ground. A comparator has a non-inverting input coupled to the first capacitive-DAC and an inverting input coupled to the second capacitive-DAC, and outputs a value indicating a comparison between voltages at its inputs. A SAR logic block stores an output binary value indicative of an approximated digital representation of an analog differential signal based on the comparator output. The SAR ADC samples the differential analog signal through the positive and negative input terminals and converts the sampled signal using charge redistribution steps in the first and second capacitive DACs under control of a shifting code and the output binary value.

### PRIORITY CLAIM

This application claims the priority benefit of Italian application for Patent No. 102025000010419 filed on May 8, 2025, the content of which is hereby incorporated by reference in its entirety to the maximum extent allowable by law.

### TECHNICAL FIELD

Various embodiments of the present disclosure relate to Analog to Digital Converters.

### BACKGROUND

Numerous integrated circuit products utilize Analog to Digital Converters (ADCs) for transforming analog measurements such as voltages, currents, and temperatures into digital values.

A widespread type of Analog-to-Digital converter is the successive-approximation register (SAR) ADC, thanks to its capability of achieving high resolutions and conversion speeds, while offering a low power consumption and retaining a relatively simple design.

The successive-approximation register ADC digitizes each sample from a continuous analog waveform using a binary search through all possible quantization levels.

To this end, the successive-approximation register analog-to-digital converter circuit typically comprises a sample-and-hold circuit that acquires the input voltage, an analog voltage comparator that compares the input voltage to the output of a digital-to-analog converter (DAC), a successive-approximation register that is updated by results of the comparator to provide the DAC with a digital code whose accuracy increases each successive iteration, and a DAC that supplies the comparator with an analog voltage relative to a reference voltage, which corresponds to the full-scale range of the ADC, and proportional to the digital code of the SAR.

The successive-approximation register is initialized with logic 1 in the most significant bit (MSB) and logic zeroes in the lower bits. The register code is fed into the DAC, which provides an analog equivalent of its digital code to the comparator for comparison with the sampled input voltage. If such an analog voltage exceeds the input voltage, then the comparator causes the SAR to reset this bit to logic 0; otherwise, the bit is left as logic 1. Then the next bit is set to logic 1 and the same test is done, continuing this binary search until every bit in the SAR has been tested. The resulting code is the digital approximated output of the sampled input voltage.

A commonly adopted SAR ADC implementation uses a charge-scaling DAC consisting of an array of individually-switched capacitors sized in powers of two and an additional duplicate of the smallest capacitor, for a total of N+1 capacitors for N bits. Thus, if the largest capacitance is C, the smaller capacitances have sizes equal to C/2, C/4, C/8, C/16, etc., and the total capacitance of the capacitor array is 2C.

The switched capacitor array acts as both the sample-and-hold element and the DAC. Redistributing the charge among the capacitors adjusts their net voltage, which is fed into the comparator to perform the binary search.

These converters are typically operated in single-ended or fully differential modes.

Single-ended mode measures an analog signal voltage with respect to a fixed ground reference point. In this mode, one input terminal is coupled to the signal source, whereas the other remains connected to ground. This approach typically allows for simplified circuit designs, but is more susceptible to electrical noise and common-mode disturbances.

On the other hand, the fully differential mode measures the voltage difference between two signal lines, which are driven with opposite polarity signals. Both input terminals are active, with one measuring a positive signal and the other a complementary negative signal. This mode provides superior noise immunity, as common-mode noise affects both signal lines equally and can be effectively cancelled during signal processing. Differential measurements advantageously reduce ground loop effects, minimize electromagnetic interference, and offer more accurate signal representation across the input range.

However, the existing measurement approaches employed in fully differential SAR ADCs present significant inefficiencies in input range utilization. In fact, since most telemetry measurements are positive, ADCs typically utilize only half of their differential input range, thus requiring large input ranges, causing an unnecessary increase of the Least Significant Bit (LSB) voltages, and causing amplified integral non-linearity, and heightened noise and signal chain offsets.

Current technical solutions attempting to address these issues incorporate analog offset at the measurement chain input for shifting differential voltage to cover full ADC range. However, these approaches introduce additional measurement chain errors, reduce electrical noise immunity, and limit the capability to measure negative offsets during Auto-Zero phases.

FIG. 1 is illustrative of an exemplary differential successive approximation ADC circuit 99 realized in accordance with solutions known in the art. As pictured, the differential SAR ADC 99 comprises a positive input terminal VINP, and a negative input terminal VINM. The positive input terminal VINP is coupled to a positive C-DAC 112, and the negative input terminal VINM is coupled to a negative C-DAC 114.

The positive C-DAC 112 includes a first capacitor bank C20 comprising a plurality of capacitances, each comprising a respective first and second terminal. The first terminals of the capacitances C20 are selectively couplable by means of a first array of switches S20 to a reference voltage VREF, to a ground reference GND, or to the positive input terminal VINP. Similarly, the negative C-DAC 114 includes a second capacitor bank C40, each comprising a respective first and second terminal. The first terminals of the capacitances C40 are selectively couplable through a second array of switches S40 to the reference voltage VREF, to the ground reference GND, and to the negative input terminal VINM.

In particular, in a first sampling phase the first switch array S20 is configured to couple the first terminals of the first capacitor bank C20 to the positive input terminal VINP, and similarly the second switch array S40 is configured to couple the first terminals of the second capacitor bank C40 to the negative input terminal VINM, thus enabling the sampling of an input differential analog signal VD, which is received through the positive input terminal VINP and the negative input terminal VINM. At the end of such sampling phase, the capacitor banks C20 and C40 store a voltage indicative of the sampled differential analog signal VD, which is to be converted in the subsequent conversion phase through multiple charge redistribution steps.

The second terminals of the first capacitor bank C20 of the positive C-DAC 112 are coupled to a positive terminal VP of a comparator 130, whereas the second terminals of the second capacitor bank C40 of the negative C-DAC 114 are coupled to a negative terminal VM of the comparator 130.

In turn, during each conversion step the comparator 130 compares the voltages at its positive terminal VP and at its negative terminal VM, and consequently outputs an output signal directed to a SAR logic block 140. To this end, the comparator 130 has an output terminal VO coupled to the SAR logic block 140.

The SAR logic block 140 stores the output signal of the comparator 130 for forming an output code CO which is the approximated digital representation of the input differential analog signal VD. The output code CO is fed back to the positive C-DAC 112 and the negative C-DAC 114 for controlling the switches S20 and S40 coupling the first terminals of the capacitor banks C20 and C40 either to the voltage reference VREF or to the ground reference GND.

Specifically, each bit of the output code is associated to a capacitance in the capacitor bank of the positive C-DAC 112 and of the negative C-DAC 114.

As illustrated, the output code is received at the negative C-DAC 114 through an inverter 120, in such a way that the negative C-DAC 114 receives the negated replica of each bit of the output code CO received at the positive C-DAC 112. This way, the switches of the second switch array S40 are inversely driven with respect to the switches of the first switch array S20. Thus, for example, when a capacitance associated to a certain bit is coupled to the voltage reference in the first C-DAC 112, it will be coupled to the ground reference GND in the second C-DAC 114, and vice-versa.

The SAR logic block 140 controls the SAR ADC circuit 99 for determining the approximate digital representation CO of the input signal VD by performing a binary search through the comparator 130. Each bit is thus determined based on the comparison between the voltage at the non-inverting input VP and the inverting input VM of the comparator 130. Such voltages vary at each conversion step due to the feedback signal output by the SAR logic block 140, which controls the capacitor switches S20 and S40 causing charge redistribution among the capacitances comprised in each capacitor arrays C20 and C40.

As mentioned, the differential SAR ADC circuit 99 carries out conversion of the differential analog signal VD received at the positive input terminal VINP and at the negative input terminal VINM through a sampling phase and a conversion phase.

In the sampling step, the differential analog signal VD to be converted is sampled and stored in the capacitor arrays, by coupling the capacitor banks C20 and C40 to the positive and negative input terminals VINP and VINM as discussed before. During this phase, a common mode voltage VCM corresponding to the common mode portion of the differential signal VD is coupled to the input terminals of the comparator 130. On the other hand, the output of the comparator 130 is ignored in this step.

As illustrated, the positive terminal VP and the negative terminal VM of the comparator 130 are respectively coupled to the bottom plates of the first capacitor bank C20 and to the bottom plates of the second capacitor bank C40. A pair of switches also allows the coupling of the positive input terminal VP and of the negative input terminal VM of the comparator 130 to the common mode voltage node VCM, thus enabling the sampling of the input differential voltage VD, as it will be made clearer in the following of the present description. In other words, the positive input terminal VP and the negative input terminal VM are coupled to the bottom plates of the first and second capacitor banks C20 and C40, and can be coupled to the common mode voltage VCM by closing the respective switches.

Hence, during the sampling phase the capacitance banks C20 and C40 are charged by a voltage comprised between the differential input voltage VD and the common mode voltage VCM. It is noted that the value of the common mode voltage VCM does not impact the differential portion VD of the sampled signal, and thus does not affect the result of the conversion. Hence, while during the sampling phase the output of the comparator 130 is ignored, the provided switches allow to feed a well-defined signal (i.e., the common mode voltage VCM) to the input terminals of the comparator 130.

In the one or more subsequent charge redistribution steps, the output code CO corresponding to the input differential signal VD is determined through a binary search, starting from the Most Significant Bit (MSB) and ending the conversion when the Least Significant Bit (LSB) is determined. During the conversion, the charge stored in the capacitor arrays is redistributed among the capacitances, and the number of charge redistribution steps varies according to the desired resolution of the application.

FIG. 2A illustrates a detailed schematic diagram of a possible embodiment of differential SAR ADC circuit 99 implementing a 5-bit SAR ADC, shown in a configuration for sampling the input analog signal VD.

As the considered example of differential SAR ADC circuit 99 is configured to provide a resolution of 5 bits, the first capacitor array C20 and the second capacitor array C40 comprise six capacitances each.

In particular, the first capacitor array comprises a first capacitance C21 having a capacitance value equal to C, a second capacitance C22 having a value of C/2, a third capacitance C23 having a value of C/4, a fourth capacitance C24 having a value of C/8, a fifth capacitance C25 having a value of C/16, and a sixth capacitance having a value of C/16. Thus, the total capacitance of the first capacitor bank is equal to 2C.

Similarly, the capacitances comprised in the second capacitor bank i.e., the capacitances C41, . . . , C46, have corresponding capacitance values with respect to the corresponding capacitances in the first capacitor bank C20, thus also the total capacitance of the second capacitor bank is equal to 2C.

The first terminals of the capacitances comprised in the first capacitor bank (i.e., the capacitances C21, . . . , C26) are coupled to respective switches comprised in the first switch array S20. Each capacitance C21, . . . , C26 has the first terminal coupled to a ground switch S21a, . . . , S26a and to a reference switch S21b, . . . , S26b, respectively allowing the coupling of the first terminal to the ground reference GND, and to the voltage reference VREF or the positive input terminal VINP.

Specifically, the first capacitance C21 has the first terminal coupled to a ground switch S21a and to a reference switch S21b. The ground switch S21a allows to couple the first terminal of the first capacitance C21 to the ground reference GND, whereas the reference switch S21b allows to couple the first terminal of the first capacitance C21 either to the voltage reference VREF or to the positive input terminal VINP.

As illustrated, when the reference switch S21b is closed and the ground switch S21a is opened, it is possible to selectively couple either the voltage reference VREF or the positive input terminal VINP to the first terminal of the first capacitance C21 by controlling a first switch S12.

The remaining capacitances C22, . . . , C26 of the first capacitor bank C20 are coupled to respective ground switches S22a, . . . , S26a and reference switches S22b, . . . , S26b of the first switch array S20 accordingly.

In a similar fashion, the first terminals of the capacitances C41, . . . , C46 comprised in the second capacitor bank C40 are coupled to respective switches comprised in the second switch array S40, through which are selectively couplable to the ground reference GND, and to the voltage reference VREF or the negative input terminal VINM.

In particular, each capacitance C41, . . . , C46 has the first terminal coupled to a ground switch S41a, . . . , S46a for allowing the coupling to the ground reference GND, and to a reference switch S41b, . . . , S46b for allowing the coupling to the voltage reference VREF or to the negative input terminal VINM.

A second switch S14 allows to select whether to couple the first terminals of the capacitances C41, . . . , C46 to the voltage reference VREF or to the negative input terminal VINM when the respective reference switches S41b, . . . , S46b are closed and the ground switches S41a, . . . , S46a are opened.

The second terminals of the first capacitor array C20 (i.e., each second terminal of the capacitances C21, . . . , C26 comprised in the first capacitor array C20) are coupled to the positive input terminal VP of the comparator 130.

Similarly, the second terminals of the second capacitor array C40 (i.e., each second terminal of the capacitances C41, . . . , C46 comprised in the second capacitor array C40) are coupled to the negative input terminal VM of the comparator 130.

In the first sampling phase, the first terminals of the first capacitor array C20 of the first C-DAC 112 are coupled to the positive input terminal VINP through the first switch S12, and the first terminals of the second capacitor array C40 are coupled to the negative input terminal VINM through the second switch S14.

The positive input terminal VINP and the negative input terminal VINM are coupled, through a voltage follower 125, to both the positive input terminal VP and the negative input terminal VM of the comparator 130. The paths coupling the output terminal of the voltage follower 125 are interrupted by a third switch S17, which is coupled to the positive input terminal of the comparator 130, and by a fourth switch S19, which is coupled to the negative input terminal of the comparator 130.

This way, the voltage obtained at the output terminal of the voltage follower 125 is the common mode voltage VICM of the input signal, which is defined as VICM=(VINP+VINM)/2. Accordingly, the second terminals of both the first capacitor array C20 and the second capacitor array C40 are coupled to the common mode voltage VICM during the sampling phase, thanks to the third switch S17 and the fourth switch S19 being closed.

The differential voltage VD is defined as the difference of the positive input voltage VINP and the negative input voltage VINM (i.e., VD=VINP−VINM).

At the sampling phase, the voltage across the first capacitor array C20 (i.e., the voltage measured across the first terminals and second terminals of each capacitance C21, . . . , C26 of the capacitor array C20), is equal to −VD/2 (i.e., (VINM−VINP)/2), thus a total charge Q20=−2C*VD/2 is stored in the first capacitor array C20.

Accordingly, the voltage across the second capacitor array C40 is equal to VD/2 (i.e., (VINP−VINM)/2), meaning that a total charge Q40=2C*VD/2 is stored in the second capacitor array C40.

As the sampling of the input voltages is performed, the SAR ADC 99 consequently initiates the conversion phase, comprising one or more charge redistribution steps.

In this regard, FIG. 2B is illustrative of a schematic showing the differential SAR ADC circuit 99 as configured during a first charge redistribution step (i.e., a first conversion step).

In general, SAR ADC circuits such as the exemplary differential SAR ADC circuit 99 described herein, commence the determination of the output code CO from the Most Significant Bit (MSB), then perform the subsequent conversion steps until the Least Significant Bit (LSB) is determined. The output code CO resulting from the conversion of the analog quantity is determined bit after bit. The bit determined at each conversion step is employed in the subsequent conversion step for modifying the configuration of the DACs 112 and 114, thus implementing the aforementioned dichotomic search mechanism.

In the example considered, the differential SAR ADC circuit 99 implements a 5-bit converter, thus the output code CO corresponding to the differential analog signal VD acquired through the positive input terminal VINP and the negative input terminal VINM is converted and expressed using five bits (e.g., a fifth bit B4, a fourth bit B3, a third bit B2, a second bit B1, and a first bit B0), where the fifth bit B4 represents the Most Significant Bit (MSB) and the first bit B0 represents the Least Significant Bit (LSB).

In particular, during the conversion phase (i.e., during the present first charge redistribution step and the subsequent charge redistribution steps), the first switch S12 and the second switch S14 are configured to respectively couple the first switch array S20 and the second switch array S40 to the reference voltage VREF.

Further, in the conversion phase the third switch S17 and the fourth switch S19 are opened, in such a way that the second terminals of the first capacitor bank C20 and of the second capacitor bank C40 are decoupled from the output of the voltage follower 125 (i.e., from the common mode voltage VICM). That way, the second terminals of the first capacitor bank C20 and of the second capacitor bank C40 are still respectively coupled to the positive input terminal VP and to the negative input terminal VM of the comparator 130, while being decoupled from the common mode voltage VICM.

During the first charge redistribution step, the SAR ADC 99 couples the first terminal of the first capacitance C21 to the reference voltage VREF, by opening the ground switch S21a, and by closing the reference switch S21b.

As illustrated, the remaining capacitances of the first capacitor bank C20 (i.e., the second capacitance C22, the third capacitance C23, the fourth capacitance C24, the fifth capacitance C25, and the sixth capacitance C26) have the first terminals coupled to the ground reference voltage GND, by closing the respective ground switches S22a, . . . , S26a coupled thereto, and opening respective reference switches S22b, . . . , S26b.

In a similar fashion, the first terminal of the first capacitance C41, comprised in the second capacitor array C40 of the second C-DAC 114, is coupled to the ground reference voltage GND, by closing the first ground switch S41a and by opening the first reference switch S41b.

The remaining capacitances of the second capacitor array C40 (i.e., the second capacitance C42, the third capacitance C43, the fourth capacitance C44, the fifth capacitance C45, and the sixth capacitance C46) are coupled to the reference voltage VREF by opening the respective ground switches S42a, . . . , S46a, and by closing the respective reference switches S42b, . . . , S46b.

In particular, the sixth capacitance C26 of the first capacitor array C20 has the first terminal constantly coupled to the ground reference voltage GND throughout the first sampling phase and the subsequent conversion phase and, similarly, the sixth capacitance C46 of the second capacitor array C40 has its first terminal constantly coupled to the reference voltage VREF throughout the first sampling phase and the subsequent charge redistribution steps.

In accordance with the configuration here described, the comparator 130 outputs a signal VO indicative of the result of the comparison between the voltage at its positive input terminal VP and the voltage at its negative input terminal VM, in particular outputting a logic high value if the voltage at its positive input terminal VP is greater than the voltage at its negative input terminal VM and, vice-versa, outputting a logic low value if the voltage at its positive input terminal VP is smaller than the voltage at its negative input terminal VM.

During the first charge redistribution step, the variation of the voltage at the positive input terminal VP of the comparator 130 is due to the redistribution of charge in the first capacitor array C20.

As mentioned above, the total charge Q20 stored in the first capacitor array C20 is equal to Q20=−2C*VD/2. During the first charge redistribution step, the charge is redistributed across the first capacitor array C20, due to the fact that the first capacitance C21 is biased with the reference voltage VREF, while the other capacitances C22, . . . , C26 have respective first terminals coupled to the ground reference voltage GND. As a consequence, the total charge Q20 can be expressed as:

$${Q}_{20} = ( {V}_{P} - {V}_{REF} ) \cdot C + ( {V}_{P} - 0 ) \cdot ( \frac{C}{2} + \frac{C}{4} + \frac{C}{8} + \frac{C}{16} + \frac{C}{16} )$$

Therefore, the voltage VP at the positive input terminal of the comparator 130, which is induced by the connection of the first terminal of the first capacitance C21 to the voltage reference VREF, while the remaining capacitances C22, . . . , C26 have the first terminals coupled to the ground reference GND, can be expressed as VP=VREF/2−VD/2.

Similarly, the variation of the voltage at the negative input terminal VM of the comparator 130 is due to the redistribution of charge in the second capacitor array C40 caused by the connection of the first terminal of the first capacitance C41 to the ground reference GND, while the remaining capacitances C42, . . . , C46 have the first terminals coupled to the voltage reference VREF. Thus, the voltage at the negative input terminal is VM=VREF/2+VD/2.

Accordingly, the comparator 130 produces as output voltage VO=A*(VP−VM), where the value A is equal to the open-loop gain of the comparator 130.

In response to detecting an output voltage VO greater than zero (i.e., VO>0), the SAR logic block 140 determines that the determined value for the fifth bit B4 (i.e., the MSB is a ‘0’), and consequently stores such value in a register.

If the fifth bit B4 is found to be equal to ‘0’, the SAR logic block 140 reverts the connection of the switches S21a and S21b coupled to the first capacitance C21, and of the switches S41a and S41b coupled to the first capacitance C41. Thus, in this case the SAR logic block 140 couples the first terminal of the first capacitance C21 of the first capacitor array C20 to the ground reference GND, and the first terminal of the first capacitance C41 of the second capacitor array C40 to the reference voltage VREF.

On the contrary, in response to detecting an output voltage VO smaller than zero (i.e., VO<0), the SAR logic block 140 determines that the fifth bit B4, is equal to ‘1’, and stores such value in the register. In this case, the SAR logic block 140 does not modify the configuration of the switches in the positive C-DAC 112 and in the negative C-DAC 114, thus leaves the first terminal of the first capacitance C21 of the first capacitor array C20 coupled to the reference voltage VREF, and the first terminal of the first capacitance C41 of the second capacitor array C40 coupled to the ground reference GND.

The register comprised in the SAR logic block 140 may be for instance a dedicated register for storing the output code CO.

Successively, a subsequent charge redistribution step is initiated in order to determine the value of the successive bit, which in the example considered is the fourth bit B3.

In this regard, FIG. 2C is illustrative of the configuration of the differential SAR ADC circuit 99 during the determination of the fourth bit B3, in the case where the fifth bit B4 (i.e., the MSB), is equal to 1.

As illustrated, the ground switch S21a coupled to the first capacitance C21 of the first switch array S20 is opened, while the reference switch S21b coupled to the same capacitance C21 is closed, in accordance with the previous conversion step, in order to keep the first terminal of the first capacitance C21 coupled to the reference voltage VREF.

Accordingly, the ground switch S41a of the second switch array S40 in closed, while the first reference switch S41b of the second switch array S40 is opened, in accordance with the previous conversion step, in order to keep the first terminal of the first capacitance C41 of the second capacitor bank C40 coupled to the ground reference GND.

The first terminal of the capacitance in the positive C-DAC 112 corresponding to the fourth bit B3 (i.e., the second capacitance C22 of the first capacitor array C20) is coupled to the reference voltage VREF by opening the respective ground switch S22a and by closing the respective reference switch S22b.

In a similar fashion, the first terminal of the capacitance of the negative C-DAC 114 corresponding to the fourth bit B3 (i.e., the second capacitance C42 of the second capacitor array C40) is coupled to the ground reference GND by closing the respective ground switch S42a and by opening the respective reference switch S42b.

The remaining smaller capacitances in the first capacitor bank C20 (i.e., the capacitances C23, . . . , C26 comprised therein) have the first terminals coupled to the ground reference GND through the closing of the respective ground switches S23a, . . . , S26a, and the opening of the respective reference switches S23b, . . . , S26b.

Similarly, the remaining smaller capacitances in the second capacitor bank C40 (i.e., the capacitances C43, . . . , C46 comprised therein) have the first terminals coupled to the reference voltage VREF through the opening of the respective ground switches S43a, . . . , S46a, and the closing of the respective reference switches S43b, . . . , S46b.

The variation of the voltage at the positive input terminal VP of the comparator 130 is due to the redistribution of charge in the first capacitor array C20. In particular, the variation of voltage at the non-inverting input terminal VP of the comparator 130 is due to the connection of the first terminal of the capacitance C22, associated to the fourth bit B3, to the reference voltage VREF, and to the connection of the first terminal of the larger capacitance C21 and of first terminals of the smaller capacitances C23, . . . , C26 to the ground reference GND.

The charge Q20 stored in the first capacitor bank C20 can thus be expressed as:

$${Q}_{20} = ( {V}_{P} - {V}_{REF} ) \cdot ( C + \frac{C}{2} ) + ( {V}_{P} - 0 ) \cdot ( \frac{C}{4} + \frac{C}{8} + \frac{C}{16} + \frac{C}{16} )$$

Therefore, the voltage at the non-inverting input terminal VP of the comparator 130 is VP=¾*VREF−VD/2.

Similarly, the voltage at the negative input terminal VM of the comparator 130 is due to the redistribution of charge in the second capacitor array C40, in particular to the connection of the first terminal of the first capacitance C41 of the second capacitor array C40 to the ground reference GND, and to the connection of the first terminals of the capacitances C42, . . . , C46 to the voltage reference VREF.

Thus, the voltage at the inverting input VM of the comparator 130 is VM=VREF/4+VD/2.

Accordingly, the comparator 130 compares the voltages at the positive input terminal VP and at the negative input terminal VM, and consequently outputs the signal VO indicative of such comparison, as performed in the previous conversion step. In this regard, the output voltage of the comparator 130 is VO=A*(−VD+VREF/2).

The SAR logic block 140 determines of the basis of the output value VO the value of the fourth bit B3, and consequently stores it in the register.

As performed in the previous charge redistribution step, if it is determined that the fourth bit B3 is equal to 0, the connection of the corresponding capacitances C22 and C42 is reverted, thus the first terminal of the second capacitance C22 in the first capacitor bank C20 is coupled to ground, whereas the first terminal of the second capacitance C42 in the second capacitor bank C40 is coupled to the voltage reference VREF.

Conversely, if it is determined that the fourth bit B3 is equal to 1, the connection of the corresponding capacitances C22 and C42 is not changed, hence the first terminal of the second capacitance C22 in the first capacitor bank C20 is left coupled to the voltage reference VREF, and the first terminal of the second capacitance C42 in the second capacitor bank C40 is left coupled to the ground reference GND for the determination of the subsequent bits B2, . . . , B0.

Referring again to the previous charge redistribution step represented in FIG. 2B, where the SAR logic block 140 determines the value of the fifth bit B4, if such fifth bit B4 (i.e., the MSB), is equal to 0, the ground switch S21a coupled to the first capacitance C21 of the first capacitor bank is closed, while the reference switch S21b coupled to the same capacitance C21 is opened, in order to keep the first terminal of the first capacitance C21 of the first capacitor bank C20 coupled to the ground reference GND.

In this case, the ground switch S41a of the second switch array S40, which is coupled to the first capacitance C41 of the second capacitor bank C40, is opened, while the first reference switch S41b coupled to the same capacitance C41 is closed, in order to keep the first terminal of the first capacitance C41 of the second capacitor bank C40 coupled to the reference voltage VREF.

Thus, if the fifth bit B4 is equal to 0, the configuration of the switches associated to the fifth bit B4 in the first switch array S20 and in the second switch array S40 is reverted.

In this regard, FIG. 2D is illustrative of the configuration of the SAR ADC 99 during the determination of the fourth bit B3, in the case where the fifth bit B4 (i.e., the MSB), is equal to 0.

As illustrated, the configuration of the switches associated to the fifth bit B4 in the first switch array S20 and in the second switch array S40 is reverted with respect to the configuration illustrated in FIG. 2C, whereas the remaining switches, associated to smaller capacitances, are configured in the same way.

The variation of voltage at the positive input terminal VP of the comparator 130 is due to the connection of the first terminal of the second capacitor C22 of the first capacitor bank C20 to the reference voltage VREF, and the connection of the first terminals of the remaining capacitors having smaller capacitance (i.e., the capacitors C23, C24, C25, and C26) to the ground reference GND.

Similarly, the variation of voltage at the negative input terminal VM is induced by the connection of the first terminal of the second capacitor C42 of the second capacitor bank C40 to the ground reference GND, and the coupling of the first terminals of the remaining smaller capacitances (i.e., the capacitances C43, C44, C45, and C46) to the reference voltage VREF.

Accordingly, the total charge Q20 present in the first capacitor bank C20 is:

$${Q}_{20} = ( {V}_{P} - {V}_{REF} ) \cdot \frac{C}{2} + ( {V}_{P} - 0 ) \cdot ( C + \frac{C}{4} + \frac{C}{8} + \frac{C}{16} + \frac{C}{16} )$$

Therefore, the voltage at the positive input terminal VP is VP=¼*VREF−VD/2, whereas the voltage at the negative input terminal VM is VM=¾*VREF+VD/2.

As discussed previously, the comparator 130 outputs the result of the comparison between the voltage at its positive input terminal VP and the voltage at its negative input terminal VM, according to the expression VO=A*(VP−VM), which in this case yields VO=−VD−VREF/2.

The corresponding result is then stored in the SAR logic block 140 as determined value of the fourth bit B3.

On the basis of such value, the switches associated to the fourth bit B3 (i.e., the switches S22a and S22b in the first switch array S20, and the switches S42a and S42b in the second switch array S40) are configured accordingly.

In particular, if it is determined that the fourth bit B3 is equal to 0, the connection of the corresponding switches is reverted for the subsequent conversion steps, thus the first terminal of the second capacitance C22 of the first capacitor array C20 is coupled to the ground reference GND, and the first terminal of the second capacitance C42 of the second capacitor array C40 is coupled to the reference voltage VREF.

On the contrary, if it is determined that the fourth bit B3 is equal to 1, the connection of the switches is not changed, thus the first terminal of the second capacitance C22 of the first capacitor array C20 is left coupled to the voltage reference VREF, whereas the first terminal of the second capacitance C42 of the second capacitor array C40 is left coupled to the ground reference GND.

At the end of the second conversion step, the differential SAR ADC circuit 99 initiates a third charge redistribution step for determining the third bit B2, which is performed in a similar way with respect to the second conversion step described in the foregoing. Successively, the differential SAR ADC 99 performs a fourth conversion step for determining the value of the second bit B1, and finally performs a fifth conversion step for determining the value of the first bit B0 (i.e., the LSB).

Specifically, in each subsequent charge redistribution step, the configuration of the first switch array S20 and of the second switch array S40 is changed on the basis of the value taken by the bit determined in the previous conversion step, as in the case discussed above, where the switches corresponding to the fifth bit B4 are configured on the basis of the value of the fifth bit B4 during the determination of the fourth bit B3.

Thus, for determining the value of the third bit B2, the differential SAR ADC circuit 99 considers the value of the fourth bit B3 for configuring the switches array S20 and S40, along with the value of the fifth bit B4. Similarly, the SAR ADC 99 considers the value of the third bit B2, the fourth bit B3, and the fifth bit B4 in the determination of the second bit B1, and considers the value of such second bit B1, the third bit B2, the fourth bit B3, and the fifth bit B4 for determining the first bit B0 (i.e., the LSB).

Thus, in general, the feedback signal output from the SAR logic block 140 is employed for controlling the switch arrays S20 and S40 respectively comprised in the positive C-DAC 112 and in the negative C-DAC 114, for gradually narrowing the range of comparison and implementing thereby the dichotomic search procedure.

FIG. 3A illustrates a plot of a differential voltage signal VD, highlighting the limits that mark the differential input voltage range of the differential SAR ADC circuit 99. As pictured, the input voltage range of the SAR ADC circuit 99 is limited by the reference voltage VREF, which sets the lower bound of the input voltage range at −VREF and the upper bound at +VREF. The differential input voltage range of the SAR ADC circuit 99 as described herein is thus equal to 2*VREF, hence a differential voltage comprised within such input voltage range can be correctly acquired by the SAR ADC circuit 99.

FIG. 3B illustrates a plot of the voltage at the positive input terminal VINP, and of the voltage at the negative input terminal VINM, the difference of which results in the differential voltage signal VD shown in the plot of FIG. 3A. As illustrated, the positive input voltage VINP and the negative input voltage VINM are defined with respect to the common mode voltage VICM, which is placed in the middle of the vertical axis for convenience since, as known per se, the common mode voltage VICM is defined as VICM=(VINP+VINM)/2.

FIG. 3C illustrates a plot of the corresponding output code for the input signal represented in FIGS. 3A and 3B (i.e., the differential voltage VD and the voltage at the positive input terminal VINP and at the negative input terminal VINM).

As illustrated, values corresponding to the upper limit of the input voltage range (i.e., values having a voltage equal to +VREF), are represented by an output code equal to 11111=25-1 in the exemplary SAR ADC circuit 99 as shown in FIGS. 2A, . . . , 2D, or in general as 2ⁿ−1, n indicating the bits of resolution of the SAR ADC, while values having a voltage equal to −VREF (i.e., values corresponding to the lower limit of the input voltage range) are represented by an output code equal to 00000=0.

Further, when the differential voltage VD is equal to zero (i.e., when the line of the differential voltage signal VD crosses the horizontal axis in the plot of FIG. 3A), the corresponding output code is equal to half of the output range (i.e., 01111=15 in the exemplary SAR ADC circuit 99 shown in FIGS. 2A, . . . , 2D), or in general as 2ⁿ⁻¹−1. Thus, differential voltages greater than zero will be expressed by a corresponding output code having the MSB equal to 1, and on the contrary differential voltages VD smaller than zero will be expressed by corresponding output codes having the MSB equal to 0.

FIG. 4 illustrates the differential input range VR of the exemplary 5-bits differential SAR ADC circuit 99.

As illustrated, the differential input range VR of the differential SAR ADC circuit 99 is equal to 2*VREF. The voltage associated to the LSB is equal to VREF/16, which represents the smallest voltage difference that the differential SAR ADC circuit 99 can distinguish. As already described in FIG. 3C, a voltage of 0 V represents a threshold over which the measured voltage will have the MSB equal to 1, whereas voltages smaller than 0 V will be represented by the differential SAR ADC circuit 99 with the MSB equal to 0.

Further solutions of this kind are found, for instance, in United States Patent Application Publication No. 2023/0208427 A1, and Chinese Patent Application CN115765740A (both of which are incorporated herein by reference).

In view of the above, it is evident that in fully differential SAR ADCs the input range may be not fully exploited in cases where the signals to be measured are mainly positive signals, which thus left a portion of the input range of the differential SAR ADCs unused, causing unnecessary high LSB voltages that may cause difficulties in measuring small voltages.

As mentioned in the foregoing, the existing solutions attempting to solve these problems typically compromise measurement accuracy and electromagnetic compatibility, particularly when trying to perform precise offset measurements or handle small input voltages in opposite directions. Analog offsets create additional error sources, and single-ended measurement paths cannot effectively measure negative offsets during critical calibration stages.

Therefore, the need is felt for a solution capable of optimizing fully differential measurement paths, maximizing input range utilization while maintaining a high measurement accuracy, thus enabling precise offset measurement across positive and negative voltage ranges, and preserving superior noise immunity characteristics of differential measurement techniques.

There is a need in the art to contribute in addressing the issues discussed in the foregoing.

### SUMMARY

One or more embodiments concern a circuit. Embodiments moreover concern a corresponding method.

Solutions as described herein relate to a successive approximation Analog-to-Digital Converter circuit, comprising a positive input terminal, a negative input terminal, a first capacitive Digital-to-Analog Converter comprising a first capacitor bank including a plurality of capacitances, being selectively couplable to the positive input terminal, to a reference voltage, or to a ground reference, a second capacitive Digital-to-Analog Converter comprising a second capacitor bank including a plurality of capacitances, being selectively couplable to the negative input terminal, to the reference voltage, or to the ground reference, a comparator having a non-inverting input coupled to the first capacitive DAC, and an inverting input coupled to the second capacitive DAC, configured to output an output value indicative of the comparison between a voltage at the non-inverting input and a voltage at the inverting input, and a Successive Approximation Register (SAR) logic block configured to store an output binary value indicative of an approximated digital representation of an input analog differential signal on the basis of the output value of the comparator. According to solutions as described herein, the SAR ADC circuit is configured for sampling an analog differential signal through the positive input terminal and the negative input terminal, and for consequently converting the sampled analog signal by performing one or more charge redistribution steps in the first capacitive Digital-to-Analog Converter and the second capacitive Digital-to-Analog Converter under the control of a shifting code and of the output binary value.

Further, solutions as described herein relate to a method for converting a differential analog signal into a digital output code, comprising performing in the aforementioned successive approximation ADC circuit a first step of sampling the differential analog signal by respectively coupling the first terminals of the capacitances comprised in the first capacitor bank and in the second capacitor bank to the positive input terminal and to the negative input terminal, and a second step of determining each bit of the output code by performing charge redistribution, applying a predetermined shifting code to one among the first C-DAC or the second C-DAC, consequently comparing voltages at the non-inverting terminal and at the inverting terminal of the comparator, and storing the result of such comparison in a register of the SAR logic block.

In particular, such charge redistribution is performed starting from the MSB, until the LSB is determined, and comprises performing in the C-DAC not having the shifting code applied the steps of coupling the first terminals of capacitances associated to bits whose value is already determined either to the voltage reference if the corresponding bit is de-asserted and if the first C-DAC has said shifting code applied, the ground reference if the corresponding bit is asserted and if the first C-DAC has said shifting code applied, the ground reference if the corresponding bit is de-asserted and if the second C-DAC has said shifting code applied, or the voltage reference if the corresponding bit is asserted and if the second C-DAC has said shifting code applied; successively coupling the first terminal of the capacitance associated to the bit to be determined to the ground reference if the first C-DAC has said shifting code applied, or to the voltage reference if the second C-DAC has said shifting code applied; and coupling the first terminals of capacitances associated to bits whose value is yet to be determined to the voltage reference if the first C-DAC has said shifting code applied, or to the ground reference if the second C-DAC has said shifting code applied.

Solutions as described herein further relate to an integrated circuit implementing the differential SAR ADC circuit discussed above.

### BRIEF DESCRIPTION OF THE DRAWINGS

Embodiments of the present disclosure will now be described with reference to the annexed drawings, which are provided purely by way of non-limiting example and in which:

FIG. 1 shows a conventional fully differential successive approximation register (SAR) analog-to-digital converter circuit;

FIG. 2A shows a detailed schematic of an exemplary 5-bit differential SAR ADC during a sampling phase;

FIG. 2B shows the differential SAR ADC during a first charge redistribution step for determining a most significant bit;

FIG. 2C shows the differential SAR ADC during a subsequent charge redistribution step when the most significant bit has a first value;

FIG. 2D shows the differential SAR ADC during a subsequent charge redistribution step when the most significant bit has a second value;

FIG. 3A shows a plot of a differential input voltage and corresponding input voltage range limits;

FIG. 3B shows plots of positive and negative input voltages defining the differential input voltage;

FIG. 3C shows a plot of a digital output code corresponding to the differential input voltage;

FIG. 4 shows a differential input voltage range and least significant bit resolution of an exemplary differential SAR ADC;

FIG. 5 is a simplified schematic of an embodiment of SAR ADC circuit according to solutions as described herein;

FIG. 6A is a schematic diagram of a SAR ADC circuit according to solutions as described herein configured for performing a sampling phase;

FIG. 6B is a schematic diagram of a SAR ADC circuit according to solutions as described herein configured for performing a first charge redistribution step;

FIG. 6C is a schematic diagram of a SAR ADC circuit according to solutions as described herein configured for performing a second charge redistribution step;

FIG. 6D is a schematic diagram of a SAR ADC circuit according to solutions as described herein configured for performing a second charge redistribution step

FIG. 7 is a diagram representing the differential input range of a SAR ADC circuit as described herein;

FIG. 8A is a plot representing a differential signal to be converted through a SAR ADC circuit as described herein;

FIG. 8B is a plot representing voltages on a positive input terminal and on a negative input terminal of a SAR ADC circuit as described herein;

FIG. 8C is a plot representing a resulting output code corresponding to the differential signal of FIG. 8A converted through a SAR ADC circuit as described herein;

FIG. 9 is a simplified schematic of a further embodiment of SAR ADC circuit according to solutions as described herein;

FIG. 10A is a schematic diagram of a further embodiment of a SAR ADC circuit according to solutions as described herein configured for performing a sampling phase; and

FIG. 10B is a schematic diagram of a further embodiment of a SAR ADC circuit according to solutions as described herein configured for performing a first charge redistribution step.

### DETAILED DESCRIPTION

In the following description, numerous specific details are given to provide a thorough understanding of embodiments. The embodiments can be practiced without one or several specific details, or with other methods, components, materials, etc. In other instances, well-known structures, materials, or operations are not shown or described in detail to avoid obscuring aspects of the embodiments.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The references provided herein are for convenience only and do not interpret the scope or meaning of the embodiments.

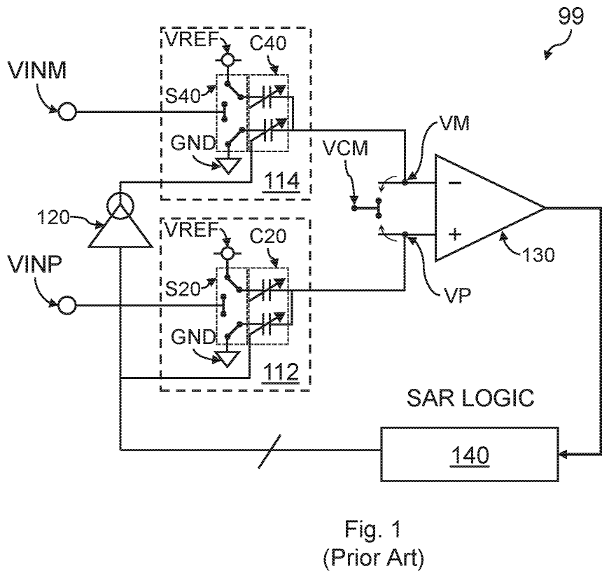

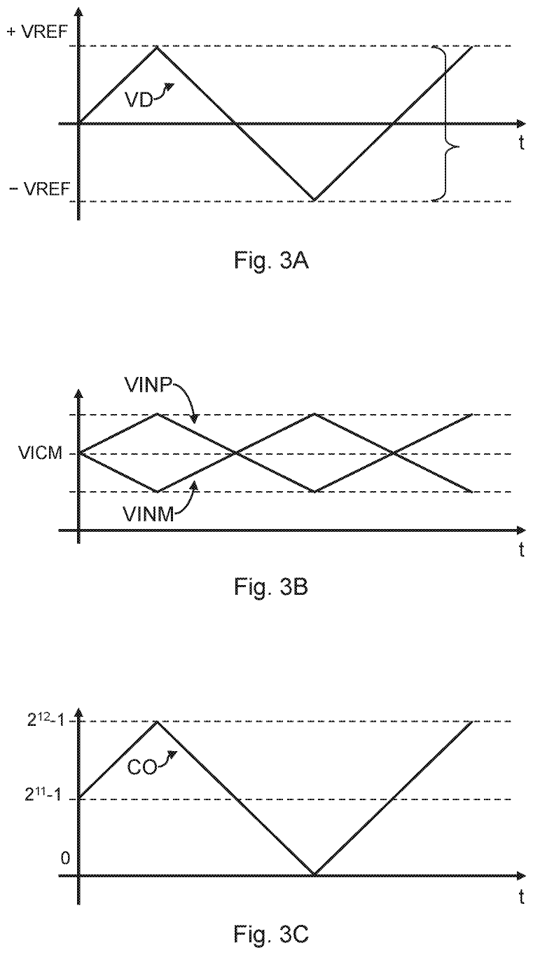

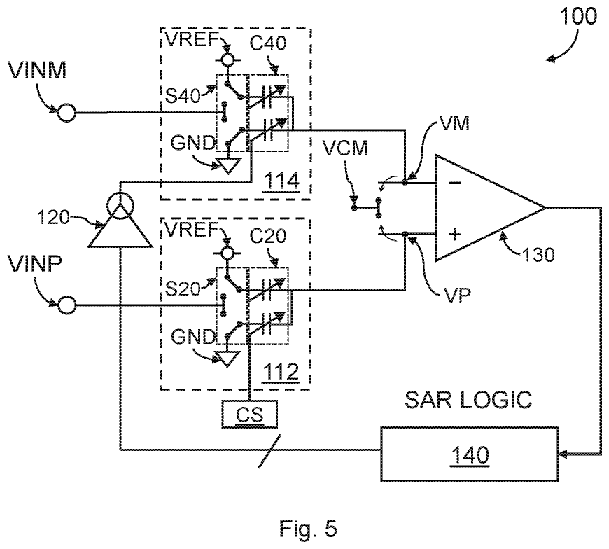

In FIGS. 5 to 10 described below, parts, elements or components that have already been described with reference to FIGS. 1 to 4 are designated by the same references used previously in these figures. The description of these elements has already been made and will not be repeated in what follows in order not to burden the present detailed description.

As mentioned before, various embodiments of the present disclosure provide solutions for converting differential analog signals into corresponding digital output codes.

In this regard, FIG. 5 is illustrative of a differential SAR ADC circuit 100 similar to the one pictured in FIG. 1 and comprising modifications according to solutions as proposed herein.

Accordingly, the differential SAR ADC circuit 100 comprises a positive input terminal VINP and a negative input terminal VINM, which are respectively coupled to a positive C-DAC 112 and to a negative C-DAC 114.

The positive C-DAC 112 comprises a first switch array S20 which is coupled to a first capacitor bank C20. In particular, as described in the foregoing, the switches comprised in the first switch array S20 are coupled to the first terminals of the capacitances included in the first capacitor bank C20, allowing to selectively couple (e.g., connect) such capacitances either to the positive input terminal VINP, to a voltage reference VREF, or to a ground reference GND.

Similarly, the negative C-DAC 114 comprises a second switch array S40 and a second capacitor bank C40, the switches of the second switch array S40 being coupled to the first terminals of the capacitances included in the second capacitor bank C40 for selectively coupling (e.g., connecting) such capacitances either to the negative input terminal VINM, to the voltage reference VREF, or to the ground reference GND.

The second terminals of the capacitances included in the first capacitor bank C20 are coupled (e.g., connected) to a positive, non-inverting, terminal VP of a comparator 130, and the second terminals of the capacitance included in the second capacitor bank C40 are coupled (e.g., connected) to a negative, inverting, terminal VM of the comparator 130.

As in the example discussed with reference made to FIG. 1, also the differential SAR ADC circuit 100 as described herein has the positive input terminal VP and the negative input terminal VM of the comparator 130 respectively coupled to the bottom plates of the first and second capacitor arrays C20 and C40, the positive input terminal VP and the negative input terminal VM being also couplable to the common mode voltage VCM during the sampling phase by closing the respective switches coupled thereto.

At each conversion step (i.e., charge redistribution step), the comparator 130 compares the voltages at its positive terminal VP and at its negative terminal VM, and outputs a corresponding output signal VO=A*(VP−VM), the parameter A indicating the open-loop gain of the comparator 130. Thus, the comparator 130 will substantially output a logic high value in case the voltage at its non-inverting terminal VP is greater than the voltage at its inverting terminal VM, and vice-versa will output a logic low value in case the voltage at its non-inverting terminal VP is less than the voltage at its inverting terminal VM.

The output signal VO output by the comparator 130 is received by a SAR logic block 140 coupled thereto, which stores such value in a register for forming the output code representing the differential input analog signal received through the positive input terminal VINP and the negative input terminal VINM.

As discussed in the foregoing, the differential SAR ADC 100 converts the input analog quantity by performing a first sampling step, where the input analog quantity is acquired through the first capacitor bank C20 and the second capacitor bank C40, and a plurality of subsequent conversion steps, where the corresponding output code is determined according to a binary search procedure, starting from the determination of the MSB and terminating at the determination of the LSB. In particular, the number of conversion steps required varies on the basis of the resolution of the SAR ADC circuit.

With reference made to the exemplary differential SAR ADC 99 discussed in the foregoing, the output code progressively formed in the register of the SAR logic block 140 is employed for controlling the values output by the positive C-DAC 112 and by the negative C-DAC 114.

On the contrary, as illustrated in FIG. 5, the differential SAR ADC circuit 100 as proposed herein employs the output code stored in the SAR logic block 140 solely for configuring the second switch array S40. The feedback signal output by the SAR logic block 140 is received as input by the negative C-DAC 114 through the inverter 120, and enables the control of the switches coupled to the capacitances comprised in the negative C-DAC 114 for performing the sampling and conversion steps.

On the contrary, in various embodiments the first switch array S20 included in the positive C-DAC 112 is controlled by an applied shifting code CS. The shifting code CS comprises a number of bits corresponding to the resolution of the SAR ADC circuit 100, as to provide a binary value for configuring the switches, and the corresponding capacitances, associated to each bit of the output code. The value of the shifting code CS is an integer number and is determined, e.g., by writing the desired value in a corresponding register, and is kept constant throughout the whole conversion process (i.e., during each charge redistribution step).

In various embodiments, the integer shifting applied to the output code of the SAR logic block 140 allows adjustment of the input voltage range of the SAR ADC 100 to a desired voltage range.

Such shifting advantageously allows spreading the output code of the SAR logic block 140 over a different voltage range. For instance, a specific voltage range achievable with the solution as proposed herein allows spreading the output code over a voltage range which is equivalent to half of the voltage range of the fully differential SAR ADC 99 as illustrated in FIG. 1.

Advantageously, such modification included in the differential SAR ADC circuit 100 allows maintaining a differential input signal, having a stable common mode, while spreading the output code over a desired range.

Further, as it will be made clearer throughout the present description, the solution proposed herein advantageously provides a tunable shifting of the differential input voltage range, allowing the measuring of voltages near to zero.

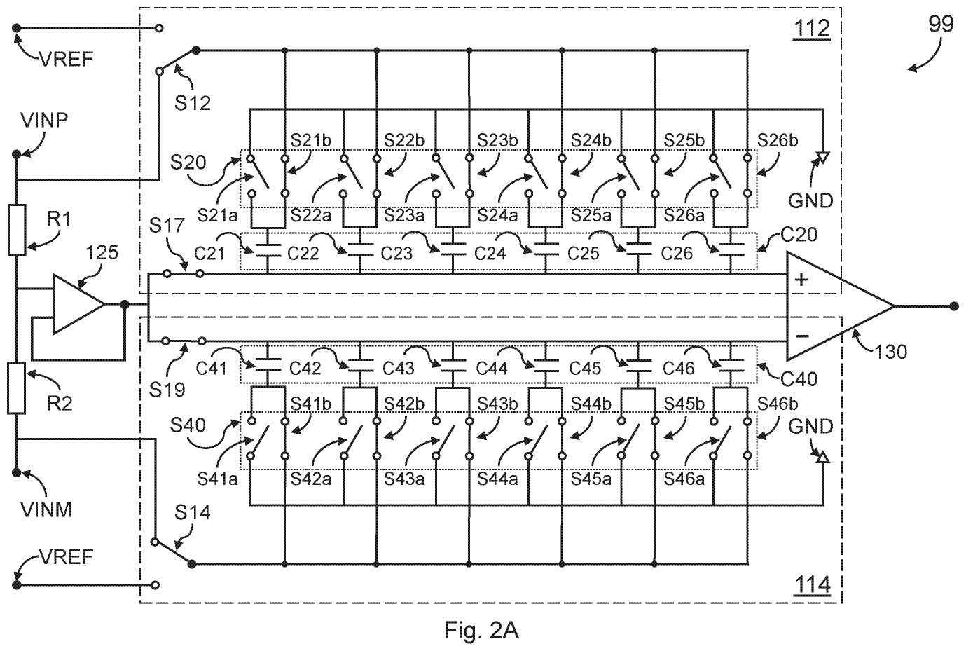

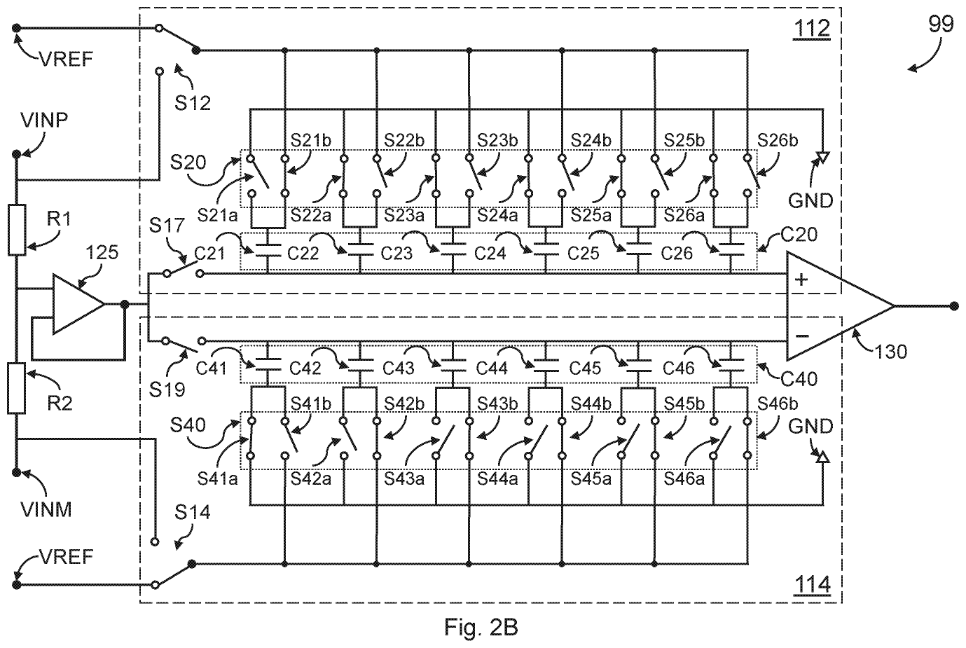

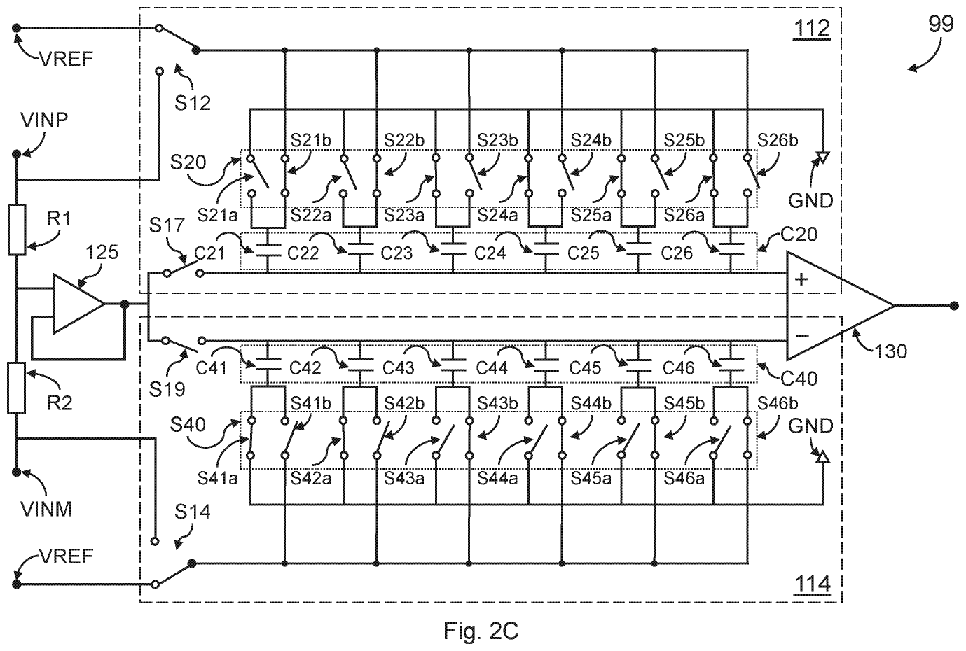

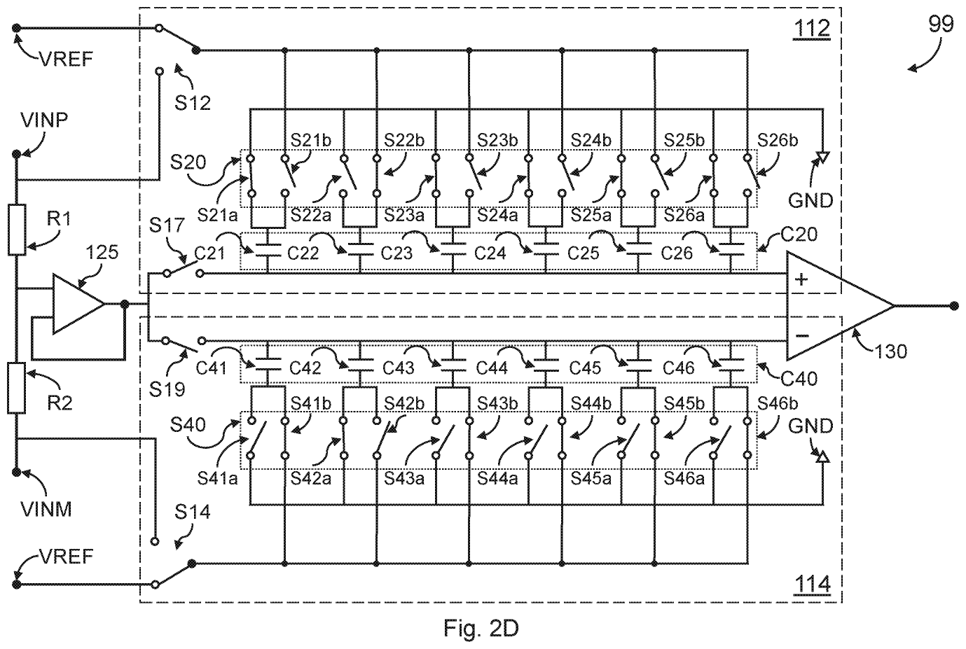

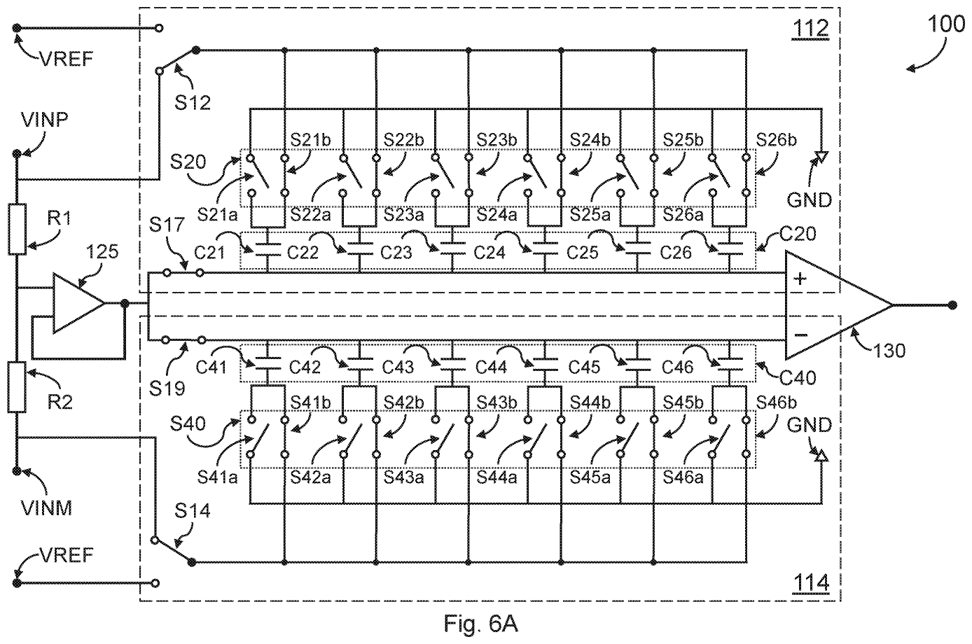

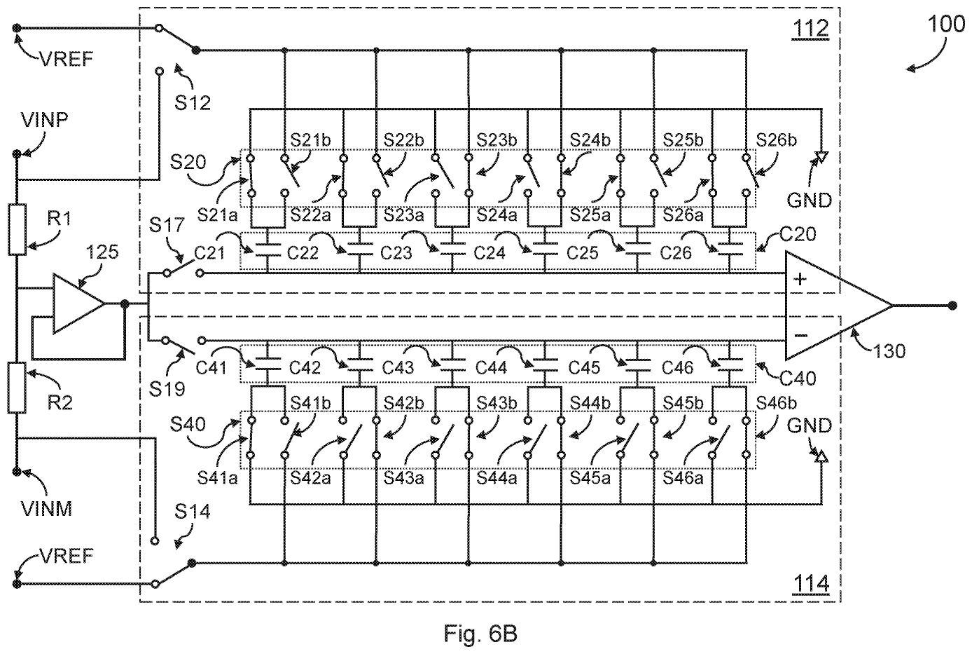

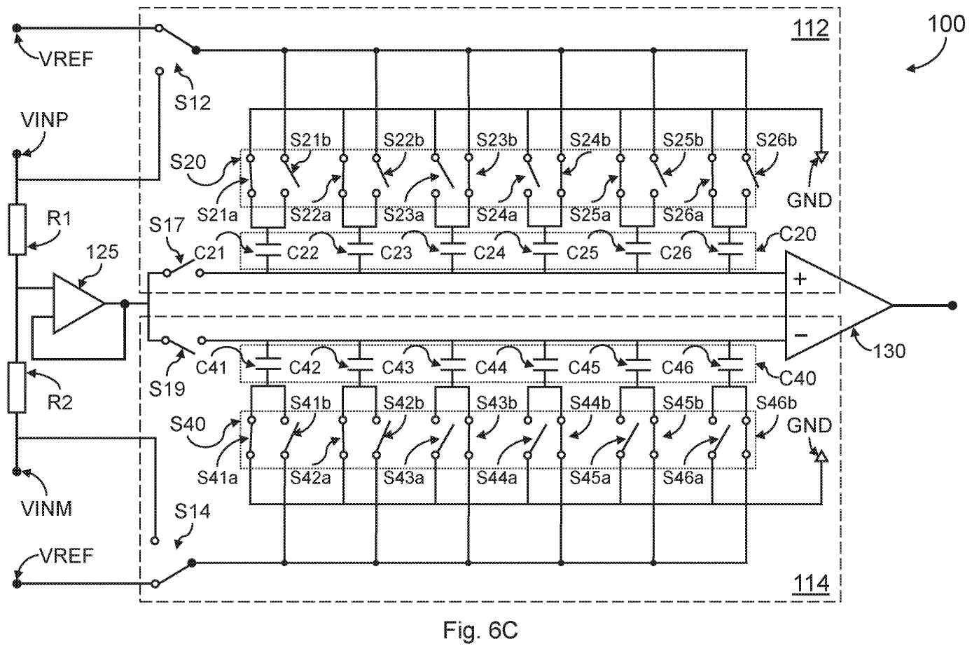

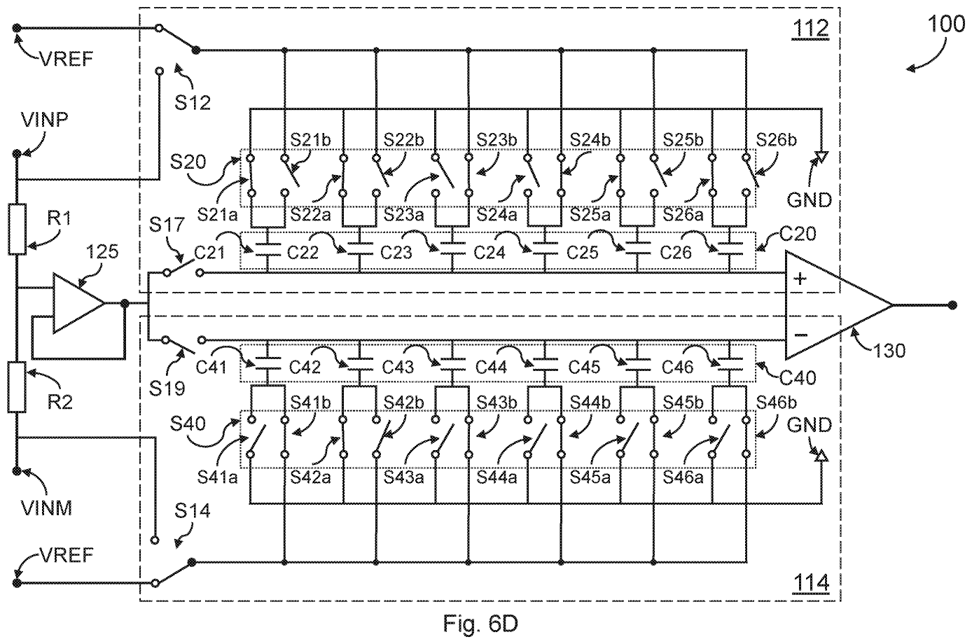

With reference made to FIGS. 6A, . . . , 6D, an exemplary embodiment of a differential SAR ADC circuit 100 according to solutions as described herein will now be described. In particular, the exemplary SAR ADC 100 described is based on the same 5 bits SAR ADC architecture as described in the foregoing and illustrated in FIGS. 2A, . . . , 2D, further comprising modifications in accordance with the solution here described. Therefore, for like parts, like references and numerals will be used in the following.

FIG. 6A is illustrative of a schematic diagram representing an exemplary embodiment of a differential SAR ADC circuit 100 according to solutions as proposed herein in a configuration for sampling the input differential analog signal.

As discussed previously, the differential SAR ADC circuit 100 comprises a positive input terminal VINP and a negative input terminal VINM, which are respectively couplable to the positive C-DAC 112 and to the negative C-DAC 114 through a first switch S12 and a second switch S14.

During the sampling phase, the first switch S12 and the second switch S14 are respectively coupling (e.g., connecting) the positive C-DAC 112 and the negative C-DAC 114 to the positive input terminal VINP and the negative input terminal VINM, respectively, while are leaving the reference voltage VREF disconnected from both the positive C-DAC 112 and the negative C-DAC 114.

A third switch S17 and a fourth switch S19 are closed in order to couple (e.g., connect) the second terminals of the capacitances included in the first capacitor bank C20 and in the second capacitor bank C40 to the common mode voltage VICM, which is sampled through a voltage follower 125. As pictured, the voltage follower 125 has its non-inverting input terminal coupled through resistances both to the positive input terminal VINP and to the negative input terminal VINM.

The second terminals of the capacitances included in the first capacitor bank C20 and in the second capacitor bank C40 are respectively coupled (e.g., connected) to the non-inverting terminal of the comparator 130 and to the inverting terminal of the comparator 130.

During the sampling phase, the switches included in the first switch array S20 and the switch S12 are coupling (e.g., connecting) the first terminals of the capacitances included in the first capacitor bank C20 to the positive input terminal VINP. In this regard, the reference switches S21b, . . . , S26b comprised in the first switch array S20 are closed in order to couple (e.g., connect) the first terminals of the capacitances C21, . . . , C26 via the electronic switch S12 to the positive input terminal VINP, whereas the corresponding ground switches S21a, . . . , S26a are opened.

Accordingly, the switches included in the second switch array S40 and the electronic switch S14 are coupling (e.g., connecting) the first terminals of the capacitances included in the second capacitor bank C40 to the negative input terminal VINM. In particular, the reference switches S41b, . . . , S46b comprised in the second switch array S40 are closed in order to couple (e.g., connect) the first terminals of the capacitances C41, . . . , C46 via the electronic switch S14 to the negative input terminal VINM, whereas the corresponding ground switches S41a, . . . , S46a are opened.

Thus, the configuration of the differential SAR ADC circuit 100 is substantially the same as the configuration of the exemplary SAR ADC 99 illustrated in FIG. 2A.

In various embodiments, the first switch array S20 and the electronic switch S12, and similarly the second switch array S40 and the electronic switch S14, may be implemented with other switching circuits adapted to implementing the same connections of the first terminals of the first capacitor bank C20 and the second capacitor bank C40.

Once the sampling of the differential analog input signal is performed, the differential SAR ADC circuit 100 may begin the iterative conversion of the sampled value into the corresponding digital output code.

In this regard, FIG. 6B is illustrative of a schematic diagram representing the same exemplary embodiment of differential SAR ADC circuit 100 as proposed herein in a configuration for performing a first conversion step (i.e., a first charge redistribution step) for determining the value of the fifth bit B4 (i.e., the MSB).

The differential SAR ADC circuit 100 in the first conversion phase begins the conversion of the input analog signal from the determination of the MSB (i.e., the fifth bit B4). To this end, the third switch S17 and the fourth switch S19 are opened, in order to decouple the second terminals of the capacitances included in the first capacitor bank C20 and in the second capacitor bank C40, the non-inverting input terminal VP and the inverting input terminal VM of the comparator 130 from the common mode voltage VICM output by the voltage follower 125.

The first switch S12 and the second switch S14 are configured in such a way that the first switch array S20 and the second switch array S40 are coupled (e.g., connect) to the reference voltage VREF. In particular, the reference switches S21b, . . . , S26b comprised in the first switch array S20 and the reference switches S41b, . . . , S46b comprised in the second switch array S40 are coupled to the reference voltage VREF, thus allowing the biasing of the first terminals of the capacitances coupled thereto when the reference switches S21b, . . . , S26b and S41b, . . . , S46b are closed.

As pictured, the first ground switch S41a included in the second switch array S40 is closed, and the first reference switch S41b comprised in the second switch array S40 is opened, thus coupling the first terminal of the first capacitance C41 of the second capacitor bank C40 to the ground reference GND. The first terminals of the remaining smaller capacitances (i.e., the second capacitance C42, the third capacitance C43, the fourth capacitance C44, the fifth capacitance C45, and the sixth capacitance C46) are coupled to the reference voltage VREF by opening the respective ground switches S42a, . . . , S46a coupled thereto, and by closing the respective reference switches S42b, . . . , S46b coupled thereto.

In other words, during the first conversion step the switches comprised in the second switch array S40 are configured according to the hypothesis that the MSB is equal to 1.

In various embodiments, the switches comprised in the first switch array S20 are controlled by the applied shifting code CS. The shifting code CS comprises a number of bits equal to the number of bits of resolution of the SAR ADC.

Thus, with reference made to the example illustrated in FIG. 6B, the applied shifting code CS is a five-bit binary number comprising a first bit A0, which is regarded as the LSB, a second bit A1, a third A2, a fourth bit A3, and a fifth bit A4, which is regarded as the MSB. In the example illustrated in FIG. 6B, the applied shifting code CS has a value equal to ‘11001’ (i.e., 25 in decimal).

In various embodiments, each bit of the shifting code CS determines whether the first terminal of the corresponding capacitance is to be coupled to the voltage reference VREF or to the ground reference GND. In particular, if a certain bit in the shifting code CS has a value equal to ‘1’, the first terminal of the corresponding capacitance in the first capacitor bank C20 is coupled to the ground reference GND. Conversely, if a bit in the shifting code CS has a value equal to ‘0’, the first terminal of the corresponding capacitance in the first capacitor bank C20 is coupled to the voltage reference VREF.

As anticipated, the shifting code CS applied for controlling the configuration of the first switch array S20 is constant throughout the charge redistribution process, thus all the conversion step will employ the same value of the shifting code CS e.g., ‘11001’ in the example illustrated in FIGS. 6A, . . . , 6D.

In accordance with what is known in the art for differential SAR ADC circuits, as the SAR ADC circuit 99 described in the foregoing, the differential SAR ADC circuit 100 determines the value of the fifth bit B4 (i.e., the MSB), by comparing the voltage at the non-inverting input VP of the comparator 130 with the voltage at the inverting input VM, returning an output value VO equal to ‘1’ if the voltage at the non-inverting input VP is greater than the voltage at the voltage at the inverting input VM and, conversely, returning an output value VO equal to ‘0’ if the voltage at the non-inverting input VP in smaller than the voltage at the inverting input VM, in accordance with the expression VO=A*(VP−VM).

Then, the output value VO corresponding to the fifth bit B4 (i.e., the MSB), is stored in a register of the SAR logic block 140, and the differential SAR ADC circuit 100 begins the determination of the subsequent bit (i.e., the fourth bit B3).

In this regard, FIG. 6C is illustrative of a schematic diagram representing the differential SAR ADC circuit 100 in a configuration for performing a second conversion step for determining the value of the fourth bit B3, in the hypothesis that the determined value for the fifth bit B4 is ‘0’.

As illustrated, the second switch array S40 is configured in accordance with differential SAR ADC circuits known in the art e.g., the exemplary differential SAR ADC circuit 99 described in the foregoing with reference made to FIG. 2C.

Specifically, since the value of the fifth bit B4 is equal to ‘0’, the first terminal of the first capacitance C41 of the second capacitor bank C40, which is associated to the fifth bit B4, is coupled to the voltage reference VREF, by opening the corresponding ground switch S41a and by closing the corresponding reference switch S41b.

The second capacitance C42 of the second capacitor bank C40, which is associated to the fourth bit B3 (i.e., the bit which is determined in this conversion phase), is coupled to the ground reference GND by closing the corresponding ground switch S42a and by opening the corresponding reference switch S42b.

The capacitances of the second capacitor bank having smaller values than the capacitance associated to the bit being determined (i.e., having smaller values than the second capacitance C42 in this conversion step), hence the third, fourth, fifth, and sixth capacitances C43, . . . , C46, are coupled to the voltage reference VREF by opening the corresponding ground switches S43a, . . . , S46a, and by closing the corresponding reference switches S43b, . . . , S46b.

Thus, in general, in each conversion step the capacitance in the second capacitor bank C40 associated to the bit being determined has the first terminal coupled to the ground reference GND, the capacitances having smaller values than the capacitance of the bit being determined have the first terminals coupled to the reference voltage VREF, and the capacitances having larger values, which are associated to bits whose values are known, have the first terminal coupled to the reference voltage VREF is the corresponding bits are equal to ‘0’, and have the first terminal coupled to the ground reference GND if the corresponding bits are equal to ‘1’.

As noted in the foregoing, the sixth capacitance C46 of the second capacitor bank C40 has the first terminal always coupled to the reference voltage VREF throughout the conversion process (i.e., through each charge redistribution step).

In various embodiments, the capacitances of the first capacitor bank C20 are still configured as in the previous conversion step, since the shifting code CS controlling the configuration of the switches does not change throughout the conversion process.

Thus, in the example considered, where the applied shifting code has a value equal to ‘11001’, the first capacitance C21 and the second capacitance C22 have the first terminals coupled to the ground reference GND, the third capacitance C23 and the fourth capacitance C24 have the first terminals coupled to the voltage reference VREF, and the fifth capacitance C25 has the first terminal coupled to the ground reference GND.

As noted in the foregoing, the sixth capacitance C26 of the first capacitor bank C20 has the first terminal always coupled to the ground reference GND throughout the conversion process (i.e., through each charge redistribution step).

FIG. 6D is illustrative of a further example, where the differential SAR ADC circuit 100 is configured to determine the fourth bit B3 in the hypothesis that the determined value for the fifth bit B4 is ‘1’.

As illustrated, since the value of the fifth bit B4 is equal to ‘1’, the first capacitance C41 of the second capacitor bank C40 has the first terminal coupled to the ground reference GND. The second capacitance C42 of the second capacitor banks C40 has the first terminal coupled to the ground reference GND, whereas the remaining capacitances having smaller values (i.e., the capacitances C43, . . . , C46) have the respective first terminals coupled to the reference voltage VREF.

The first capacitor bank C20 is configured as the previous examples, since the applied shifting code CS has the same value ‘11001’. Thus, the first capacitance C21 and the second capacitance C22 have the respective first terminals coupled to the ground reference GND, the third capacitance C23 and the fourth capacitance C24 have the first terminals coupled to the voltage reference VREF, and the fifth capacitance C25 and the sixth capacitance C26 have the first terminals coupled to the ground reference GND.

In general, it is possible to express the total charge Q20 stored in the first capacitor bank C20 as a sum of contribution by the capacitances whose first terminal is coupled to the reference voltage VREF, and by the capacitances whose first terminal is coupled to the ground reference GND.

Thus, the total charge Q20 stored in the first capacitor bank C20 is

$$Q 20 = C \times [ ( {V}_{P} - {V}_{R} ) \times {\sum }_{i = 0}^{4} ( \frac{1}{{2}^{4 - i}} \times \overline{{A}_{i}} ) + ( {V}_{P} - 0 ) \times {\sum }_{i = 0}^{4} ( \frac{1}{{2}^{4 - i}} \times {A}_{i} ) + \frac{1}{{2}^{4}} ]$$

By recalling that the total charge Q20 is defined as Q20=−2C*VD/2, the expression above yields:

$$C \times {V}_{D} = {V}_{R} \times C \times [ {\sum }_{i = 0}^{4} ( \frac{1}{{2}^{4 - i}} \times \overline{{A}_{i}} ) ] - 2 \times {V}_{P} \times C$$

Where the summation term defines a shift parameter S depending on each bit Ai of the shifting code CS:

$$S = {\sum }_{i = 0}^{4} ( \frac{1}{{2}^{4 - i}} \times \overline{{A}_{i}} )$$

Hence, the shift parameter S can take values ranging from 1/16 to 31/16. In the example considered, where the shifting code CS is equal to ‘11001’, the corresponding shift parameter S takes a value equal to 19/16.

The voltage at the non-inverting terminal VP of the comparator 130 can be expressed as:

$${V}_{P} = \frac{{V}_{R}}{2} \times S - \frac{{V}_{D}}{2} ,$$

whereas the voltage at the inverting terminal VM of the comparator 130 can be expressed as:

$${V}_{M} = \frac{{V}_{R}}{2} + \frac{{V}_{D}}{2} .$$

On the basis of such parameter S, it is possible to define a quantity indicating the adjustment of the differential voltage input range:

$$ε = {V}_{R} - \frac{{V}_{R}}{2} \times S = {V}_{R} \times ( 1 - {\sum }_{i = 0}^{4} ( \frac{1}{2 \times {2}^{4 - i}} \times \overline{{A}_{i}} ) ) = {V}_{R} \times ( {\sum }_{i = 0}^{4} ( \frac{{A}_{i}}{2 \times {2}^{4 - i}} ) + \frac{1}{32} )$$

Further, an adjusted analog threshold value VTH splits the overall input dynamic VR in a first part which is digitally converted with MSB code=1 for VD>VTH, and a second part which is converted with MSB code=0 for VD<VTH. The adjusted analog threshold value VTH is defined as:

$${V}_{TH} = \frac{{V}_{R}}{2} \times ( S - 1 )$$

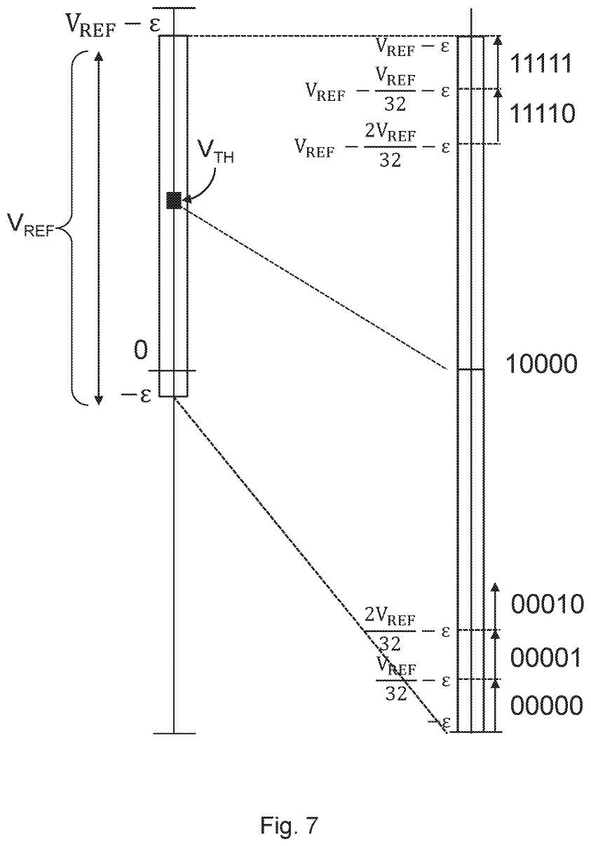

FIG. 7 is illustrative of the input range VR and the corresponding output codes of the differential SAR ADC circuit 100.

As illustrated, the input dynamic range VR of the differential SAR ADC 100 is comprised between the values-ε and VREF-ε, which represent respectively the lower bound and upper bound of the differential input range of the SAR ADC circuit 100. In the middle of the differential input range VR is highlighted the adjusted analog threshold VTH.

The lower bound-ε of the input range VR is associated to an output code equal to 0-‘00000’, whereas the upper bound of VREF-ε is associated with 31-‘11111’.

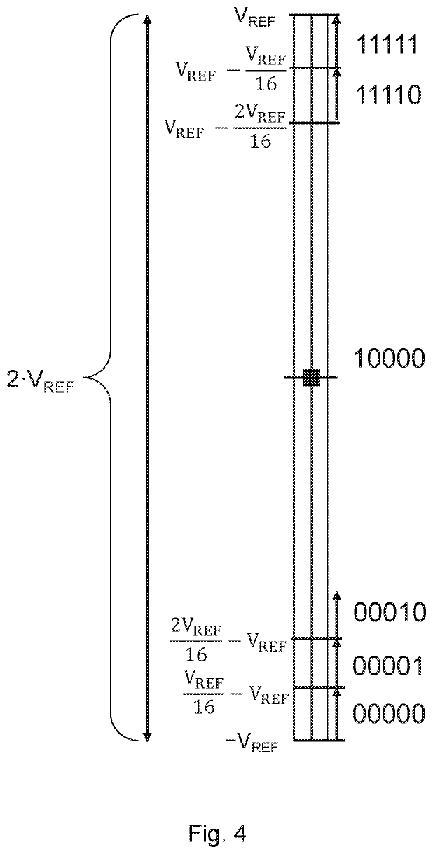

Thus, the value of the LSB using the solutions proposed herein is equal to VREF/32, which allows representation of smaller quantities with respect to traditional approaches, allowing larger input range but greater LSB, such as VREF/16 as shown in the example of FIG. 4.

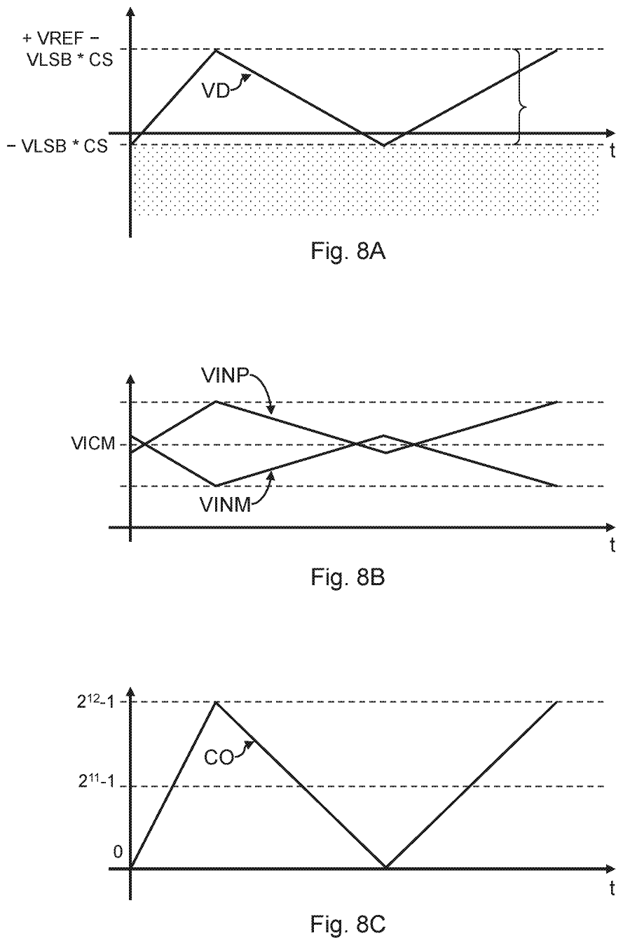

FIG. 8A is illustrative of a plot representing a differential voltage signal VD, highlighting the limits that mark the differential input voltage range VR of the differential SAR ADC circuit 100. As illustrated, the differential input range VR of the differential SAR ADC circuit 100 is limited by a lower bound equal to −VLSB*CS, where the term VLSB indicates the voltage associated to the LSB (i.e., the smallest quantity detectable by the differential SAR ADC circuit 100). The upper bound of the input range VR of the differential SAR ADC circuit 100 is equal to VREF−VLSB*CS (i.e., to the reference voltage minus the product of the voltage associated to the LSB multiplicated by the applied shifting code).

From the plot illustrated in FIG. 8A it is possible to observe that the method of operating the differential SAR ADC circuit 100 described herein allows the measurement of positive differential signals, and of small negative differential signals, thus adapting the input range VR to numerous applications.

As anticipated, the differential input range VR of the differential SAR ADC circuit 100 as described herein is equal to VREF (i.e., half of the input range VR of a classical differential SAR ADC such as the differential SAR ADC circuit 99 described in the foregoing referring to FIGS. 1 to 4).

FIG. 8B is illustrative of a plot of the voltage at the positive input terminal VINP, and of the voltage at the negative input terminal VINM, the difference of which results in the differential voltage signal VD shown in the plot of FIG. 8A. The positive input voltage VINP and the negative input voltage VINM are defined with respect to the common mode voltage VICM, which is placed in the middle of the vertical axis for convenience, and is defined as VICM=(VINP+VINM)/2.

FIG. 8C illustrates a plot of the corresponding output code for the input signal represented in FIGS. 8A and 8B (i.e., the differential voltage VD and the voltage at the positive input terminal VINP and at the negative input terminal VINM).

In such plot it is possible to appreciate the advantages of the solution as described herein, since the input range VR, described in FIG. 8A, is shrunk and the output code is spread accordingly. Hence, the LSB voltage obtainable is reduced accordingly, allowing for detection of smaller voltages.

In particular, values corresponding to the upper limit of the input voltage range (i.e., values having a voltage equal to +VREF−VLSB*CS) are represented by an output code equal to 11111=2⁵−1 in the exemplary SAR ADC circuit 100 as shown in FIGS. 6A . . . 6D, or in general as 2ⁿ−1, n indicating the bits of resolution of the SAR ADC, while values having a voltage equal to −VLSB*CS (i.e., values corresponding to the lower limit of the input voltage range are represented by an output code equal to 00000=0).

Further, when the differential voltage VD is equal to the adjusted analog threshold voltage VTH, which was defined as

$${V}_{TH} = \frac{{V}_{R}}{2} \times ( S - 1 ) ,$$

the corresponding output code is equal to half of the output range (i.e., 01111=15 in the exemplary SAR ADC circuit 100 shown in FIGS. 6A, . . . , 6D, or in general as 2ⁿ⁻¹−1). Thus, differential voltages greater than the adjusted analog threshold voltage VTH will be expressed by a corresponding output code having the MSB equal to 1, and on the contrary differential voltages VD smaller than the adjusted analog threshold voltage VTH will be expressed by corresponding output codes having the MSB equal to 0.

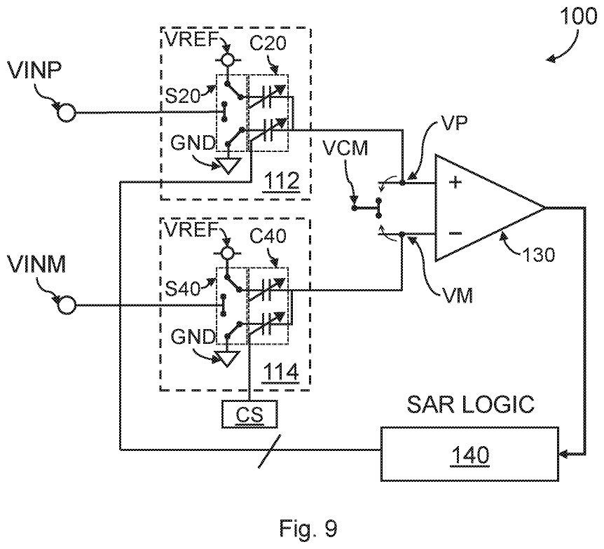

FIG. 9 illustrates a further example of differential SAR ADC circuit 100 according to the solution as proposed herein, where the configuration allows for the measurement of negative voltages. Thus, the differential input range VR of such circuit arrangement appears mirrored with respect to the horizontal axis, having a lower bound set to −VREF+VLSB*CS, and having an upper bound equal to VLSB*CS. As done with the examples discussed with reference made to FIGS. 1 and 5, also the differential SAR ADC circuit 100 presented in FIG. 9 is illustrated in a configuration for performing a charge redistribution step (i.e., with the top plates of the first and second capacitor banks C20 and C40 coupled either to the voltage reference VREF or to the ground reference GND, and with the positive input terminal VP and the negative input terminal VM of the comparator 130 coupled to the bottom plates of the first capacitor bank C20 and of the second capacitor bank C40). As illustrated, during the charge redistribution steps the positive input terminal VP and the negative input terminal VM of the comparator 130 are not coupled to the common mode voltage VCM (i.e., the switches coupling the common mode voltage node VCM and the positive and negative input terminals VP and VM are open).

As illustrated, in order to obtain a mirrored input range VR (i.e., for allowing the measurement of mostly negative differential voltages), the constant shifting code CS is applied to the negative C-DAC 114 instead of being applied to the positive C-DAC 112.

The output code CO progressively stored in the register of the SAR logic block 140 is fed back to the positive C-DAC 112, which employs the values of the output code CO without the need of an inverter for controlling the switches of the first switch array S20. Thus, in this embodiment the inverter 120 is not necessary.

The mode of operation of such an embodiment of differential SAR ADC circuit 100 is unchanged: in a first sampling phase the input differential voltage is sampled in the positive C-DAC 112 and in the negative C-DAC 114 by coupling the first terminals of capacitances comprised therein respectively to the positive input terminal VINP and to the negative input terminal VINM. In the meantime, the positive input terminal VP and the negative input terminal VM of the comparator 130 are coupled to the common mode voltage VCM, as to allow the sampling of the input voltage, by closing the respective switches coupled thereto.

In the subsequent conversion phase, the constant shifting code CS is applied for controlling the switches S40 of the negative C-DAC 114, whereas the switches S20 of the positive C-DAC 112 are controlled by the output code CO progressively determined and stored in the register of the SAR logic block 140. Also in this case, the determination of the output code CO is started from the MSB, and is concluded until the LSB is determined.

In particular, in each charge redistribution step, the conversion is started in the hypothesis that the bit to be determined is equal to 1, hence the corresponding capacitance in the first capacitor bank C20 is biased accordingly (i.e., the corresponding first terminal is coupled to the voltage reference VREF, and the first terminals of the remaining smaller capacitances are coupled to the ground reference GND).

The first terminals of the second capacitor bank C40 are coupled either to the voltage reference VREF or to the ground reference GND according to the shifting code CS. In particular, a capacitance is coupled to the voltage reference VREF if a corresponding bit in the shifting code CS is equal to ‘1’, whereas it is coupled to the ground reference GND if the corresponding bit in the shifting code CS is equal to ‘0’.

Then, the voltages at the positive terminal VP and at the negative terminal VM of the comparator 130 are compared, and the bit in the output code is determined accordingly. In particular, if the voltage at the positive terminal VP is greater than the voltage at the negative terminal VM, thus VP−VM>0, the corresponding bit in the output code CO will be a ‘0’, and the first terminal of the capacitance in the first capacitor bank C20 associated to such bit will be coupled to the ground reference GND. On the other hand, if the voltage at the positive terminal VP is smaller than the voltage at the negative terminal VM, VP−VM<0, the corresponding bit in the output code CO will be a ‘1’, and the configuration of the corresponding capacitance in the first capacitor bank C20 will not be modified.

The above procedure is iterated for each bit of the output code CO, starting from the MSB, until the LSB is determined.

As mentioned above, such arrangement of differential SAR ADC circuit 100 allows for measuring negative differential voltages VD, providing a predominantly negative input range VR, and retains the advantages of the positive differential SAR ADC circuit 100 described in the foregoing.

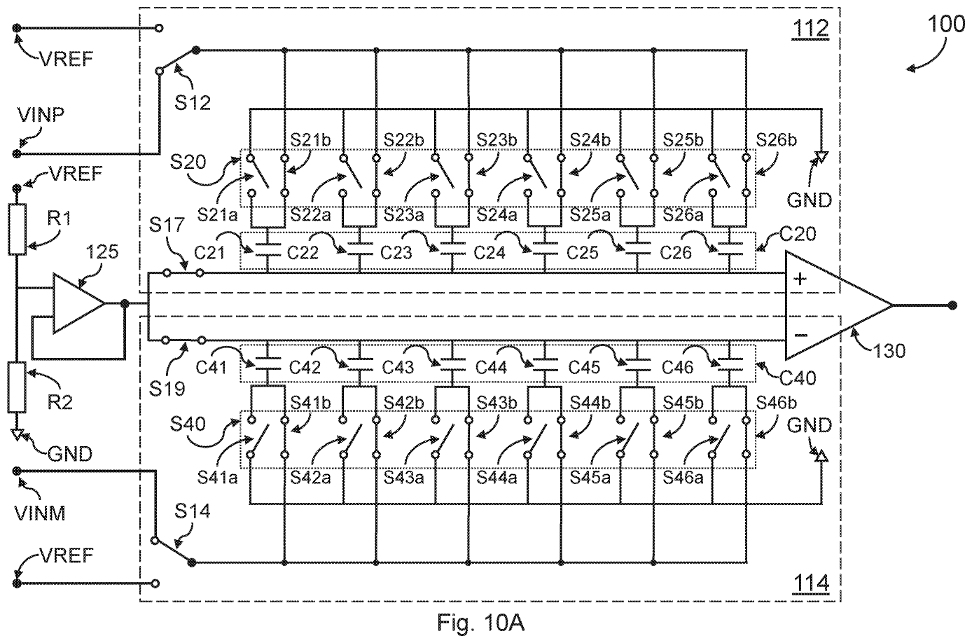

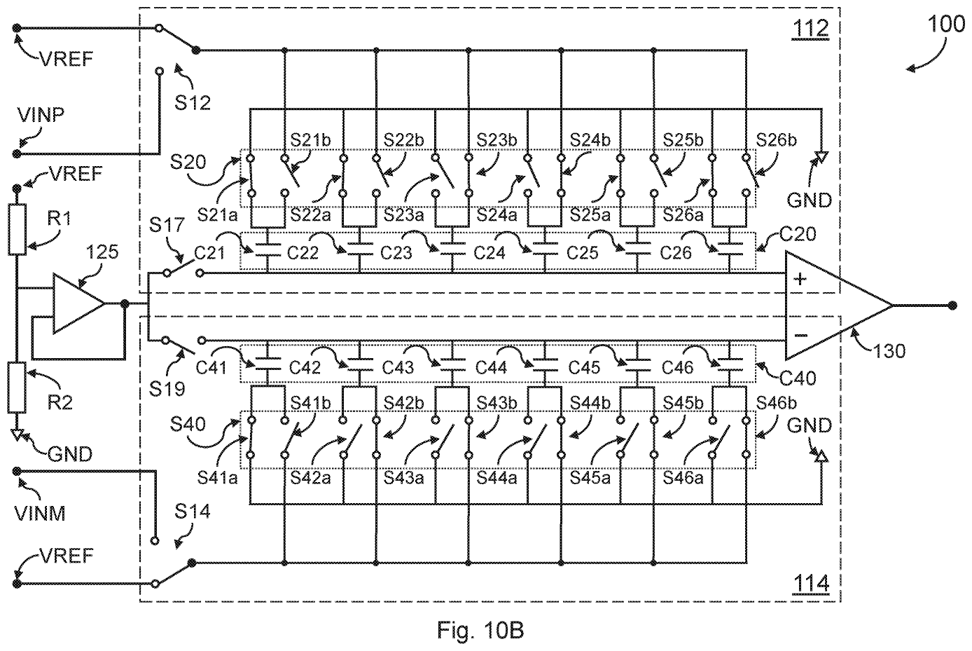

FIG. 10A is illustrative of a further embodiment of differential SAR ADC circuit 100, configured to sample the differential input signal VD.

As illustrated, in such embodiment the common mode voltage VICM is generated as part of the reference voltage VREF. To this end, the voltage follower 125 has its input terminal coupled to both the reference voltage VREF and the ground terminal GND. The input terminal of the voltage follower 125 may be coupled to a node of a voltage divider formed by two or more resistances, as the one illustrated in FIG. 10, where the voltage follower 125 input terminal is coupled to the center of a voltage divider comprising a first resistance R1 and a second resistance R2, in order to provide a stable common mode voltage VICM.

In particular, in this embodiment the common mode voltage is defined as VICM=VREF/K, where K is a constant value defined by the voltage divider (i.e., by the value of the first resistance R1 and of the second resistance R2).

When the SAR ADC circuit 100 is performing the sampling, the voltage across the first capacitor bank C20, comprised in the positive C-DAC 112, is equal to VICM-VINP, whereas the voltage across the second capacitor bank C40 is equal to VICM-VINM.

Accordingly, the charge Q20 stored in the first capacitor bank C20 is Q20=2C*VICM−2C*VINP, whereas the charge Q40 stored in the second capacitor bank C40 is Q40=2C*VICM−2C*VINM.

FIG. 10B illustrates the differential SAR ADC circuit 100 of FIG. 10A in a conversion step for determining the MSB of the output code CO.

As pictured, the first switch array S20 comprised in the positive C-DAC 112 is controlled by an applied shifting code CS having a value equal to ‘11001’, which is constant throughout all the charge redistribution steps performed.

The second switch array S40 comprised in the negative C-DAC 114 is configured in accordance with the embodiments of differential SAR ADC 100 described in the foregoing (i.e., the bit to be determined, such as the fifth bit B4 representing the MSB, is set equal to ‘1’ by coupling the first terminal of the corresponding capacitance C41 to the ground reference GND, and by coupling the first terminals of the smaller capacitances C42, . . . , C45 to the voltage reference VREF).

In particular, in this case the charge Q20 stored in the first capacitor bank C20 is:

$${Q}_{20} = ( {V}_{P} - {V}_{REF} ) \cdot C \cdot {\sum }_{i = 0}^{4} ( \frac{1}{{2}^{4 - i}} \times \overline{{A}_{i}} ) + ( {V}_{P} - 0 ) \cdot C \cdot [ {\sum }_{i = 0}^{4} ( \frac{1}{{2}^{4 - i}} \times {A}_{i} ) + \frac{1}{{2}^{4}} ]$$

Where, as previously, the value Ai indicates the i-th bit in the shifting code CS. By rearranging the equation above, the shifting parameter S is defined:

$$2 C \times {V}_{INP} - 2 C \times {V}_{ICM} = {V}_{REF} \cdot C \cdot [ {\sum }_{i = 0}^{4} ( \frac{1}{{2}^{4 - i}} \times \overline{{A}_{i}} ) ] - 2 \times {V}_{P} \cdot C$$

Accordingly, the voltage at the non-inverting terminal VP of the comparator 130 is obtained:

$${V}_{P} = \frac{{V}_{REF}}{2} \times S - {V}_{INP} + {V}_{ICM}$$

On the other hand, the voltage at the inverting terminal VM of the comparator 130 is:

$${V}_{M} = \frac{{V}_{REF}}{2} - {V}_{INM} + {V}_{ICM}$$

Therefore, the output voltage VO output by the comparator 130 is:

$${V}_{out} = G ( {V}_{P} - {V}_{M} ) = G ( - {V}_{D} + \frac{{V}_{REF}}{2} \times ( S - 1 ) ) = G ( - {V}_{D} + {V}_{TH} )$$

Where the parameter G is the open-loop gain of the comparator 130.

Thus, the obtained output voltage VO is expressed in the same way as in the embodiments previously described with reference made to FIGS. 6A, . . . , 6D.

Further embodiments of the solution as described herein are possible, for example by combining the embodiment illustrated in FIG. 9 with the embodiment illustrated in FIGS. 10A and 10B, for obtaining a differential SAR ADC circuit 100 providing a negative unipolar mode of operation and common mode voltage VICM sampled from the reference voltage VREF.

In view of the above, the features of the solution as described herein are clear, as well as its advantages. Specifically, the solution described herein provides a positive unipolar and a negative unipolar mode of operation of a differential SAR ADC circuit 100, advantageously allowing spreading of the output code CO over a range equivalent to the reference voltage VREF (i.e., half of the input range of a classical fully differential SAR ADC circui) t, while retaining capabilities of measuring both positive and negative small voltages by tuning the value of the shifting code CS accordingly.

Of course, without prejudice to the principle of the invention, the details of construction and the embodiments may vary widely with respect to what has been described and illustrated herein purely by way of example, without thereby departing from the scope of the present invention, as defined by the ensuing claims.

The scope of protection is defined in the appended claims, which form an integral part of the technical teaching of the description provided herein.

1. A successive approximation register (SAR) Analog-to-Digital Converter (ADC) circuit, comprising:
a positive input terminal and a negative input terminal;
a first capacitive Digital-to-Analog Converter (DAC) comprising a first capacitor bank including a plurality of capacitances selectively couplable to the positive input terminal, to a reference voltage, or to a ground reference;
a second capacitive Digital-to-Analog Converter (DAC) comprising a second capacitor bank including a plurality of capacitances selectively couplable to the negative input terminal, to the reference voltage, or to the ground reference;
a comparator having a non-inverting input coupled to the first capacitive DAC and an inverting input coupled to the second capacitive DAC, the comparator being configured to output a comparison signal indicative of a comparison between voltages at said non-inverting input and said inverting input; and
a successive approximation register (SAR) logic block configured to generate an output code representative of a digital approximation of a sampled differential analog input signal on the basis of said comparison signal,
wherein the SAR ADC circuit is operable in at least two selectable conversion modes including a first unipolar mode and a second unipolar mode of opposite polarity, and wherein, in each conversion mode:
a predetermined shifting code is selectively applied to only one of the first capacitive DAC or the second capacitive DAC, while the other capacitive DAC is controlled by the output code generated by the successive approximation register logic block;
the capacitive DAC to which the predetermined shifting code is applied is configured to maintain a fixed, deterministic and stable connection pattern of its capacitances to the reference voltage and/or the ground reference for an entire successive approximation conversion cycle; and
the capacitive DAC controlled by the successive approximation register logic block is configured to have its capacitances selectively reconfigured bit-by-bit during successive charge redistribution steps under control of the output code generated by the successive approximation register logic block.

2. The successive approximation ADC circuit of claim 1, wherein applying the predetermined shifting code to the first capacitive DAC configures the circuit to operate in a positive-shifted unipolar input range, and applying the predetermined shifting code to the second capacitive DAC configures the circuit to operate in a negative-shifted unipolar input range.

3. The successive approximation ADC circuit of claim 1, wherein the predetermined shifting code comprises a multi-bit digital value corresponding to the resolution of the SAR logic block.

4. The successive approximation ADC circuit of claim 1, wherein, during the successive approximation conversion cycle, the capacitive DAC controlled by the SAR logic block is reconfigured starting from a most significant bit and proceeding toward a least significant bit.

5. The successive approximation ADC circuit of claim 1, wherein the capacitances in each of the first and second capacitor banks are arranged in a binary-weighted series corresponding to respective bits of the output code.

6. The successive approximation ADC circuit of claim 1, integrated in an integrated circuit.

7. A method for converting a differential analog signal into a digital output code using a successive approximation register (SAR) Analog-to-Digital Converter (ADC) circuit comprising a first capacitive Digital-to-Analog Converter (DAC), a second capacitive Digital-to-Analog Converter (DAC), a comparator, and a successive approximation register (SAR) logic block, the method comprising:
sampling the differential analog signal onto the first and second capacitive DACs;
selectively applying a predetermined shifting code to only one of the first capacitive DAC or the second capacitive DAC;
maintaining, for an entire successive approximation conversion cycle, a stable and deterministic connection pattern of capacitances in the capacitive DAC to which the predetermined shifting code is applied;
during the same conversion cycle, controlling the other DAC by the SAR logic block by selectively reconfiguring its capacitances bit-by-bit during successive charge redistribution steps;
comparing voltages generated by the first and second capacitive DACs at respective inputs of the comparator; and
generating the digital output code based on successive comparison results produced during the successive approximation conversion cycle.

8. The method of claim 7, wherein applying the predetermined shifting code to the first capacitive DAC configures a positive-shifted unipolar conversion range, and applying the predetermined shifting code to the second capacitive DAC configures a negative-shifted unipolar conversion range.

9. The method of claim 7, wherein the successive charge redistribution steps proceed from a most significant bit toward a least significant bit under control of the successive approximation register logic block.

10. A successive approximation register (SAR) Analog-to-Digital Converter (ADC) circuit, comprising:
a positive input terminal;
a negative input terminal;
a first capacitive Digital-to-Analog Converter (DAC) comprising a first capacitor bank including a plurality of capacitances, being selectively couplable to the positive input terminal, to a reference voltage, or to a ground reference;
a second capacitive Digital-to-Analog Converter (DAC) comprising a second capacitor bank including a plurality of capacitances, being selectively couplable to the negative input terminal, to the reference voltage, or to the ground reference;
a comparator having a non-inverting input coupled to the first capacitive DAC, and an inverting input coupled to the second capacitive DAC, configured to output an output value indicative of a comparison between a voltage at the non-inverting input and a voltage at the inverting input; and
a Successive Approximation Register (SAR) logic block configured to store an output binary value indicative of an approximated digital representation of an input analog differential signal based on said output value of the comparator;
the SAR ADC circuit being configured for sampling an analog differential signal through said positive input terminal and said negative input terminal, and for consequently converting the sampled analog differential signal by performing one or more charge redistribution steps in said first capacitive Digital-to-Analog Converter and said second capacitive Digital-to-Analog Converter under control of a shifting code and of said output binary value;
wherein the SAR ADC circuit is selectively configurable in a positive shifted unipolar mode and a negative shifted unipolar mode;
wherein in the positive shifted unipolar mode, during charge redistribution in the first capacitor bank, each capacitance is coupled through a respective ground switch to the ground reference in response to a respective bit in said shifting code being asserted, and each capacitance is coupled through a respective reference switch to the reference voltage in response to a respective bit in said shifting code being de-asserted;
wherein in the negative shifted unipolar mode, during charge redistribution in the second capacitor bank, each capacitance is coupled through a respective ground switch to the ground reference in response to a respective bit in said shifting code being de-asserted, and each capacitance is coupled through a respective reference switch to the reference voltage in response to a respective bit in said shifting code being asserted;
wherein the first capacitive DAC comprises a first switch array comprising a plurality of ground switches and a plurality of reference switches, each switch of the plurality of ground switches having a first terminal coupled to a first terminal of respective capacitances in the first capacitor bank and a second terminal coupled to the ground reference, each switch of the plurality of reference switches having a first terminal coupled to the first terminal of respective capacitances in the first capacitor bank and a terminal coupled to a first switch,
wherein the second capacitive DAC comprises a second switch array comprising a plurality of ground switches and a plurality of reference switches, each switch of the plurality of ground switches having a first terminal coupled to a first terminal of respective capacitances in the second capacitor bank and a second terminal coupled to the ground reference, each switch of the plurality of reference switches having a first terminal coupled to the first terminal of respective capacitances in the second capacitor bank and a terminal coupled to a second switch,
the first switch selectively coupling the plurality of reference switches in the first switch array to the positive input terminal and to the reference voltage, the second switch selectively coupling the plurality of reference switches in the second switch array to the negative input terminal and to the reference voltage.
wherein each capacitance of the first capacitor bank has a second terminal coupled to the non-inverting input of said comparator, and each capacitance of the second capacitor bank has a second terminal coupled to the inverting input of said comparator, and further comprising a voltage follower having an input terminal coupled to a first terminal of a first resistance and to a first terminal of a second resistance, and having an output terminal couplable to the second terminals of the capacitances of the first capacitor bank and of the second capacitor bank respectively through a third switch and a fourth switch; and
wherein said first resistance has a second terminal coupled to said positive input terminal or said reference voltage, and said second resistance has a second terminal coupled to said negative input terminal or said second ground reference.

11. The successive approximation ADC of claim 10, wherein the SAR logic block determines whether to couple the first terminals of the capacitances included in the second capacitor bank to the ground reference or to the reference voltage based on the output code stored therein,
coupling the first terminal of a capacitance associated to a bit of known value in the output code either to the ground reference if such bit is asserted, or to the reference voltage if such bit is de-asserted;
coupling the first terminal of capacitances to bits whose value is yet to be determined to the reference voltage; and
coupling the first terminal of a capacitance associated to a bit which is being determined in an ongoing charge redistribution step to the ground reference.

12. The successive approximation ADC of claim 10, wherein the SAR logic block determines whether to couple the first terminals of the capacitances included in the first capacitor bank to the ground reference or to the reference voltage based on the output code stored therein,
coupling the first terminal of a capacitance associated to a bit of known value in the output code either to the ground reference if such bit is de-asserted, or to the reference voltage if such bit is asserted;
coupling the first terminal of capacitances to bits whose value is yet to be determined to the ground reference; and
coupling the first terminal of a capacitance associated to a bit which is being determined in an ongoing charge redistribution step to the reference voltage.

13. The successive approximation ADC of claim 10, wherein capacitances in the first capacitor bank and capacitances in the second capacitor bank have values which are arranged in a series forming a geometric progression with a first term being a unit capacitance, and each subsequent capacitance being half the value of a preceding one, each capacitance being associated to a corresponding bit based on its order, preferably associating a largest capacitance to a MSB, and a smallest capacitance to a LSB, last capacitances in both the first capacitor bank and in the second capacitor bank having a capacitance value equal to the capacitance associated to the LSB.

14. The successive approximation ADC of claim 10, integrated in an integrated circuit.

15. A method for converting a differential analog signal into a digital output code, comprising performing steps of:
sampling the differential analog signal by, in a successive approximation register (SAR) analog-to-digital converter circuit including a positive input terminal, a negative input terminal, a first capacitive Digital-to-Analog Converter (C-DAC) comprising a first capacitor bank having a plurality of capacitances, and a second capacitive Digital-to-Analog Converter (C-DAC) comprising a second capacitor bank having a plurality of capacitances, respectively coupling first terminals of the capacitances of the first capacitor bank to the positive input terminal and first terminals of the capacitances of the second capacitor bank to the negative input terminal;
determining each bit of the digital output code by performing charge redistribution in the SAR analog-to-digital converter circuit, including applying a predetermined shifting code to one of the first C-DAC or the second C-DAC, comparing voltages at a non-inverting input and an inverting input of a comparator of the SAR analog-to-digital converter circuit, and storing a result of the comparison in a register of a SAR logic block of the SAR analog-to-digital converter circuit;
wherein said charge redistribution is performed starting from the MSB, until the LSB is determined, and comprises performing in the C-DAC not having the shifting code applied the steps of:
coupling the first terminals of capacitances associated to bits whose value is already determined either to:
a reference voltage if the corresponding bit is de-asserted and if the first C-DAC has said shifting code applied,
a ground reference if the corresponding bit is asserted and if the first C-DAC has said shifting code applied,
the ground reference if the corresponding bit is de-asserted and if the second C-DAC has said shifting code applied, or
the reference voltage if the corresponding bit is asserted and if the second C-DAC has said shifting code applied;
coupling the first terminal of the capacitance associated to the bit to be determined to the ground reference if the first C-DAC has said shifting code applied, or to the reference voltage if the second C-DAC has said shifting code applied; and
coupling the first terminals of capacitances associated to bits whose value is yet to be determined to the reference voltage if the first C-DAC has said shifting code applied, or to the ground reference if the second C-DAC has said shifting code applied.

16. A successive approximation register (SAR) Analog-to-Digital Converter (ADC) circuit, comprising:
a positive input terminal;
a negative input terminal;
a first capacitive Digital-to-Analog Converter (DAC) comprising a first capacitor bank including a plurality of capacitances, being selectively couplable to the positive input terminal, to a reference voltage, or to a ground reference;
a second capacitive Digital-to-Analog Converter (DAC) comprising a second capacitor bank including a plurality of capacitances, being selectively couplable to the negative input terminal, to the reference voltage, or to the ground reference;
a comparator having a non-inverting input coupled to the first capacitive DAC, and an inverting input coupled to the second capacitive DAC, configured to output an output value indicative of a comparison between a voltage at the non-inverting input and a voltage at the inverting input; and
a Successive Approximation Register (SAR) logic block configured to store an output binary value indicative of an approximated digital representation of an input analog differential signal based on said output value of the comparator;
the SAR ADC circuit being configured for sampling an analog differential signal through said positive input terminal and said negative input terminal, and for consequently converting the sampled analog differential signal by performing one or more charge redistribution steps in said first capacitive Digital-to-Analog Converter and said second capacitive Digital-to-Analog Converter under control of a shifting code and of said output binary value,
wherein the shifting code determines a stable and deterministic connection of capacitances of one among the first capacitive Digital-to-Analog Converter or the second capacitive Digital-to-Analog Converter toward the ground reference and/or the reference voltage for an entire duration of a conversion cycle, while an other among the first capacitive Digital-to-Analog Converter or the second capacitive Digital-to-Analog Converter is dynamically reconfigured bit-by-bit under control of the SAR logic block during the one or more charge redistribution steps.

17. The successive approximation register (SAR) Analog-to-Digital Converter (ADC) circuit of claim 16,
wherein the shifting code is held constant for an entire conversion cycle comprising the one or more charge redistribution steps.

18. The successive approximation register (SAR) Analog-to-Digital Converter (ADC) circuit of claim 16,
wherein the shifting code is applied to the first capacitive Digital-to-Analog Converter, and the second capacitive Digital-to-Analog Converter is dynamically reconfigured bit-by-bit under control of the SAR logic block.

19. The successive approximation register (SAR) Analog-to-Digital Converter (ADC) circuit of claim 16,
wherein the shifting code is applied to the second capacitive Digital-to-Analog Converter, and the first capacitive Digital-to-Analog Converter is dynamically reconfigured bit-by-bit under control of the SAR logic block.

20. The successive approximation register (SAR) Analog-to-Digital Converter (ADC) circuit of claim 16,
further comprising an inverter coupled between an output of the SAR logic block and the dynamically reconfigured one of the first capacitive DAC and the second capacitive DAC.

21. The successive approximation register (SAR) Analog-to-Digital Converter (ADC) circuit of claim 16,
wherein capacitances in each of the first capacitor bank and the second capacitor bank are arranged in a geometric progression such that each capacitance has a value equal to half of a preceding capacitance, with a largest capacitance associated with a most significant bit and a smallest capacitance associated with a least significant bit.

22. The successive approximation register (SAR) Analog-to-Digital Converter (ADC) circuit of claim 16,
wherein second terminals of the capacitances in the first capacitor bank and the second capacitor bank are coupled to non-inverting and inverting inputs of the comparator, respectively, and are selectively couplable to a common-mode voltage during a sampling phase.

23. The successive approximation register (SAR) Analog-to-Digital Converter (ADC) circuit of claim 22,
further comprising a voltage follower configured to generate the common-mode voltage from at least one of the positive input terminal, the negative input terminal, and a reference voltage.

24. The successive approximation register (SAR) Analog-to-Digital Converter (ADC) circuit of claim 16,
wherein the SAR logic block is configured to determine bits of an output code starting from a most significant bit and proceeding sequentially to a least significant bit during the one or more charge redistribution steps.
